(19) United States
(12) Patent Application Publication
(10) Pub. No.: US 2026/0186602 A1
(43) Pub. Date: Jul. 2, 2026

(54) DISPLAY DEVICE

(71) Applicant: LG Display Co., Ltd., Seoul (KR)

(72) Inventors: Sangug AN, Gumi-si (KR); SungIl BYUN, Daegu (KR)

(73) Assignee: LG Display Co., Ltd., Seoul (KR)

(21) Appl. No.: 19/435,208

(22) Filed: Dec. 29, 2025

(30) Foreign Application Priority Data
Dec. 30, 2024 (KR) 10-2024-0201360

(51) Int. Cl. G06F 3/041; G06F 3/044; H10K 59/40; H10K 59/80

(52) U.S. Cl. CPC G06F 3/0418; G06F 3/0412; G06F 3/04164; G06F 3/04166; H10K 59/40; H10K 59/873; G06F 3/0446; G06F 2203/04111

(57) ABSTRACT

Provided is a display device including a substrate having a display area with a plurality of sub-pixels and a non-display area adjacent to the display area, an encapsulation layer disposed on the substrate, and a touch unit disposed on the encapsulation layer. The touch unit includes a plurality of touch electrodes formed of a touch metal in the display area, and a first touch line group and a second touch line group disposed in the non-display area that are respectively connected to the plurality of touch electrodes. A first touch driving signal is applied to the first touch line group, and a second touch driving signal, which is in reverse phase with the first touch driving signal, is applied to the second touch line group. Through the reverse-phase driving configuration, electromagnetic interference between touch signals can be reduced, thereby improving touch sensitivity and signal stability of the display device.

### CROSS-REFERENCE TO RELATED APPLICATIONS

This application claims the priority of Korean Patent Application No. 10-2024-0201360 filed on Dec. 30, 2024, in the Korean Intellectual Property Office, the disclosure of which is incorporated herein by reference.

### BACKGROUND

### Technical Field

The present disclosure relates to a display device, and more particularly, to a display device in which a touch unit is embedded.

### Description of the Related Art

An electroluminescent display device is a self-emitting display device and does not require a separate light source unlike a liquid crystal display device, and thus may be manufactured as a lightweight, thin display device. In addition, the electroluminescent display device is advantageous not only in terms of power consumption due to low voltage driving, but also in terms of color implementation, response speed, viewing angle, and contrast ratio (CR), so it is being studied as a next-generation display.

Among the electroluminescent display devices, there is a touch screen integrated display device including a touch unit capable of recognizing a user's touch. Since the touch screen integrated display device can directly input information using a finger or a pen, it is widely applied to navigation, portable terminals, and home appliances.

### BRIEF SUMMARY

The present disclosure relates to a display device with an embedded touch unit designed to reduce electromagnetic interference and improve touch sensitivity. Two groups of touch lines are driven with signals that are in reverse phase, which cancels interference between them. Additional pseudo lines carrying signals of opposite phase may be arranged around the display area to further suppress interference caused by wireless communication or display driving circuits, leading to a higher signal to noise ratio and more uniform touch performance.

The touch structure is integrated directly on the encapsulation layer, resulting in a thinner and lighter display. It employs dual feeding and variable length touch electrodes to balance signal delay and sensitivity across the panel, while code division multiplexing allows simultaneous multi touch detection with minimal crosstalk. These configurations ensure consistent responsiveness and stable operation even in large or high resolution panels.

Through the use of reverse phase signal driving, adaptive electrode arrangement, and optional pseudo line interference suppression within a compact layer structure, the display device achieves improved touch accuracy and uniformity without the need for additional shielding structures. This integrated configuration supports thin bezel, high performance electroluminescent displays with enhanced electromagnetic stability and simplified overall architecture.

For example, various embodiments of the present disclosure provide a display device in which a touch unit is embedded.

Various embodiments of the present disclosure provide a display device with improved performance of a touch unit.

Various embodiments of the present disclosure provide a display device in which electromagnetic interference of a touch unit is reduced.

Technical benefits of the present disclosure are not limited to the above-mentioned benefits, and other benefits, which are not mentioned above, can be clearly understood by those skilled in the art from the following descriptions.

According to an aspect of the present disclosure, a display device includes a substrate including a display area in which a plurality of sub-pixels is disposed and a non-display area surrounding the display area, an encapsulation layer disposed on the substrate, and a touch unit disposed on the encapsulation layer, the touch unit includes a plurality of touch electrodes disposed in the display area and configured by a touch metal, and a first touch line group and a second touch line group disposed in the non-display area and respectively connected to the plurality of touch electrodes, and a first touch driving signal applied to the first touch line group is in reverse phase with a second touch driving signal applied to the second touch line group.

Other detailed matters of the embodiments are included in the detailed description and the drawings.

According to the present disclosure, it is possible to provide a display device in which a touch unit is embedded.

According to the present disclosure, it is possible to provide a display device with improved performance of a touch unit.

According to the present disclosure, it is possible to alleviate electromagnetic interference of the touch unit including the pseudo line.

The effects according to the present disclosure are not limited to the contents exemplified above, and more various effects are included in the present disclosure.

### BRIEF DESCRIPTION OF THE SEVERAL VIEWS OF THE DRAWINGS

The above and other aspects, features and other advantages of the present disclosure will be more clearly understood from the following detailed description taken in conjunction with the accompanying drawings, in which:

FIG. 1 is a schematic diagram of a display device according to an exemplary embodiment of the present disclosure.

FIG. 2 is a schematic plan view of the display device according to an exemplary embodiment of the present disclosure.

FIG. 3 is a cross-sectional view of a sub-pixel of the display device according to an exemplary embodiment of the present disclosure.

FIG. 4 is an enlarged plan view of an area A1 of FIG. 2.

FIG. 5A is a cross-sectional view taken along line A-A′ of FIG. 2.

FIG. 5B is a cross-sectional view taken along line B-B′ of FIG. 2.

FIGS. 6A to 6C are schematic cross-sectional views of a dam member of the display device according to an exemplary embodiment of the present disclosure.

FIG. 7 is an enlarged plan view of an area A2 of FIG. 2.

FIGS. 8 and 9 are schematic plan views of a touch unit of the display device according to an exemplary embodiment of the present disclosure.

FIG. 10 is a schematic enlarged plan view of the touch unit of the display device according to an exemplary embodiment of the present disclosure.

FIG. 11 and FIG. 12 are schematic enlarged plan views of the touch unit of the display device according to an exemplary embodiment of the present disclosure.

FIG. 13 is a schematic plan view of a display device according to an exemplary embodiment of the present disclosure.

FIGS. 14 and 15 are enlarged plan views of an area A3 of FIG. 13.

FIG. 16 is an enlarged plan view of an area A4 of FIG. 14.

FIG. 17 is a cross-sectional view taken along line C-C′ of FIG. 16.

FIG. 18 is an enlarged plan view of an area A5 of FIG. 16.

FIG. 19 is an enlarged plan view of an area A6 of FIG. 13.

FIG. 20 is a cross-sectional view taken along line D-D′ of FIG. 19.

FIG. 21 is an enlarged plan view of an area A7 of FIG. 14.

FIG. 22A is an enlarged plan view of an area A8 of FIG. 14.

FIG. 22B is a cross-sectional view taken along line E-E′ of FIG. 22A.

FIG. 23A is an enlarged plan view of an area A8 of FIG. 14.

FIG. 23B is a cross-sectional view taken along line F-F′ of FIG. 23A.

FIG. 24 is a schematic plan view of a display device according to another exemplary embodiment of the present disclosure,

FIG. 25 is a diagram illustrating a configuration of a touch unit of a display device according to another exemplary embodiment of the present disclosure.

FIG. 26 is a view for explaining driving of a touch unit of a display device according to another exemplary embodiment of the present disclosure.

FIG. 27 is a view for explaining driving of a touch unit of a display device according to another exemplary embodiment of the present disclosure.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on,” “above,” “below,” and “next,” one or more parts may be positioned between the two parts unless the terms are used with the term “immediately” or “directly.”

When an element or layer is disposed “on” another element or layer, another layer or another element may be interposed directly on the other element or therebetween.

Although the terms “first,” “second,” and the like are used for describing various components, these components are not confined by these terms. These terms are merely used for distinguishing one component from the other components. Therefore, a first component to be mentioned below may be a second component in a technical concept of the present disclosure.

As used herein, the term “connected” is intended to have the broadest possible meaning. Specifically, the phrase “A is connected to B” encompasses both a direct connection—where no intervening components or elements are present—and an indirect connection, where one or more intermediate components or elements exist between A and B. In other words, “A is connected to B” includes both direct physical or electrical coupling and indirect coupling through one or more intervening components. Unless explicitly stated otherwise, these terms do not require direct physical or electrical contact. The term “coupled” and “in contact” should be interpreted in the same manner.

Like reference numerals generally denote like elements throughout the disclosure.

A size and a thickness of each component illustrated in the drawing are illustrated for convenience of description, and the present disclosure is not limited to the size and the thickness of the component illustrated.

The features of various embodiments of the present disclosure can be partially or entirely adhered to or combined with each other and can be interlocked and operated in technically various ways, and the embodiments can be carried out independently of or in association with each other.

Hereinafter, an exemplary embodiments of the present disclosure will be described in detail with reference to accompanying drawings.

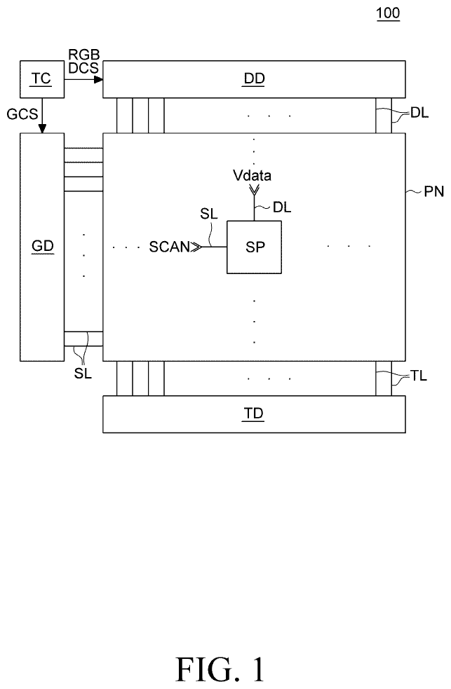

FIG. 1 is a schematic diagram of a display device according to one embodiment of the present disclosure. For convenience of explanation, in FIG. 1, only a display panel PN, a gate driver GD, a data driver DD, a touch driver TD, and a timing controller TC among the various components of a display device 100 are illustrated.

Referring to FIG. 1, the display device 100 includes the display panel PN including a plurality of sub-pixels SP, the gate driver GD and the data driver DD that supply various signals to the display panel PN, the timing controller TC that controls the gate driver GD and the data driver DD, and the touch driver TD for sensing a touch input.

The display panel PN is configured to display images to a user and includes the plurality of sub-pixels SP. In the display panel PN, a plurality of scan lines SL and a plurality of data lines DL intersect each other, and each of the plurality of sub-pixels SP is connected to the scan line SL and the data line DL. In addition, although not illustrated in the drawings, each of the plurality of sub-pixels SP may be connected to a high-potential power line, a low-potential power line, a reference line, or the like.

The plurality of sub-pixels SP is the minimum units that constitute a screen, and each of the plurality of sub-pixels SP includes a light-emitting diode and a pixel circuit for driving the light-emitting diode. The plurality of light-emitting diodes may be defined differently depending on the type of the display device 100. For example, when the display device 100 is an organic light-emitting display device 100, the light-emitting diode may be an organic light-emitting diode (OLED).

The gate driver GD supplies a plurality of scan signals SCAN to the plurality of scan lines SL according to a plurality of gate control signals GCS provided from the timing controller TC. In FIG. 1, one gate driver GD is illustrated as being spaced apart from one side of the display panel PN, but the number and disposition of the gate drivers GD are not limited thereto.

The data driver DD converts image data RGB transmitted from the timing controller TC into data voltage Vdata using a reference gamma voltage according to a plurality of data control signals DCS provided from the timing controller TC. The data driver DD may supply the converted data voltage Vdata to the plurality of data lines DL.

The timing controller TC aligns the image data RGB input from the outside and supplies the image data RGB to the data driver DD. The timing controller TC may generate the gate control signal GCS and the data control signal DCS using externally input synchronization signals, such as a dot clock signal, a data enable signal, and a horizontal/vertical synchronization signal. In addition, the timing controller TC may control the gate driver GD and the data driver DD by supplying the generated gate control signal GCS and data control signal DCS to the gate driver GD and the data driver DD, respectively.

The touch driver TD drives the touch unit 150 during the touch sensing period based on a touch enable signal input from the timing controller TC or the external component. The touch unit 150 may sense a touch input based on a signal from the touch driver TD.

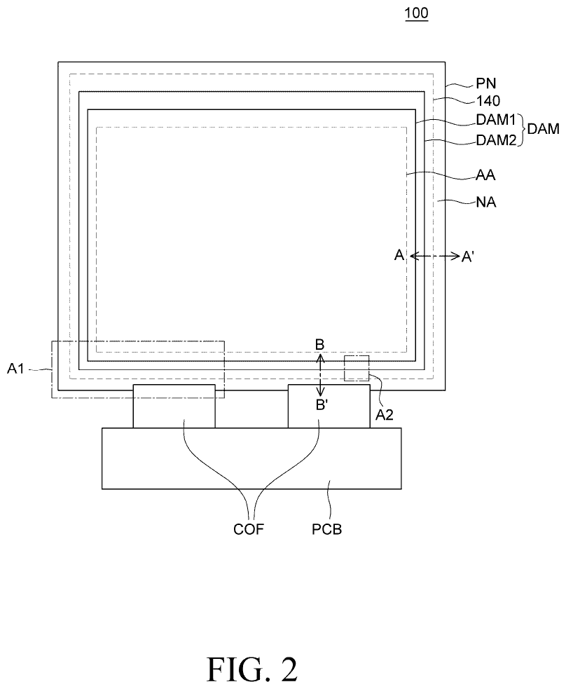

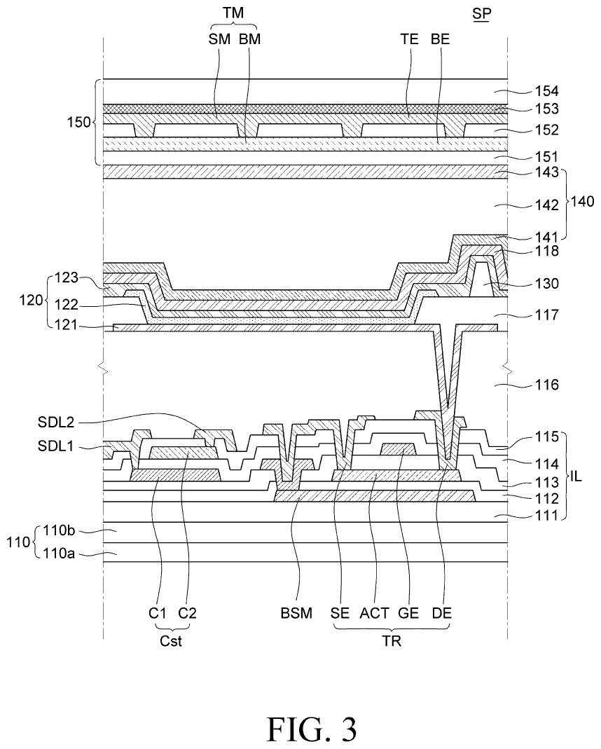

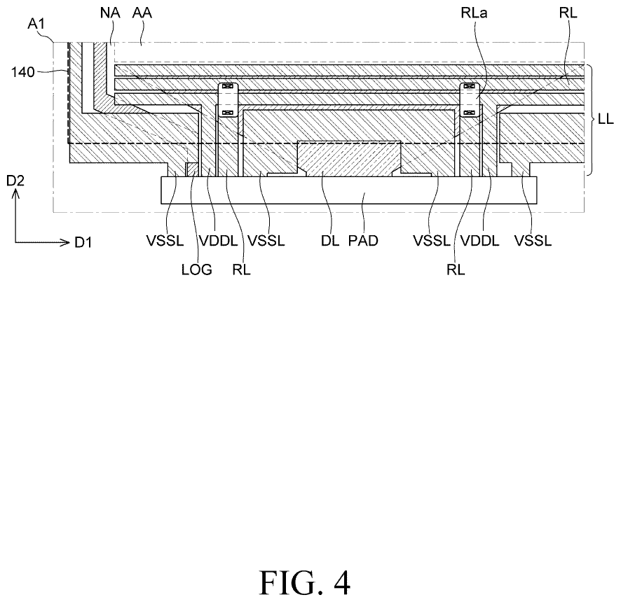

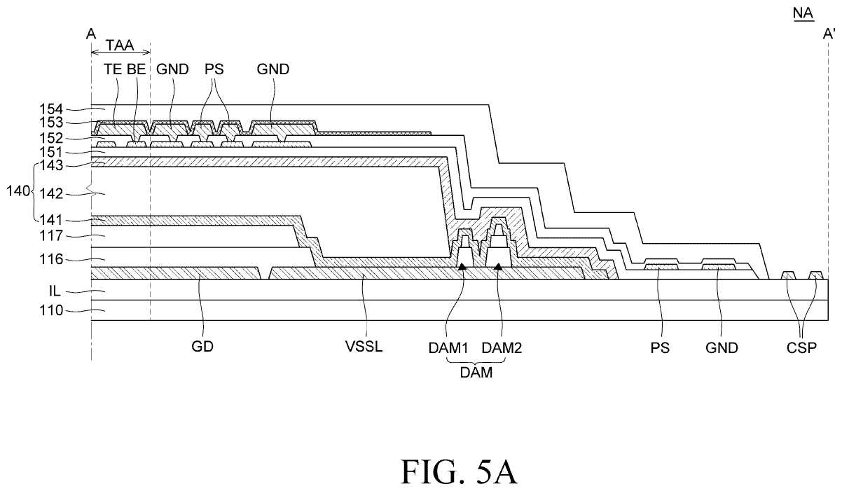

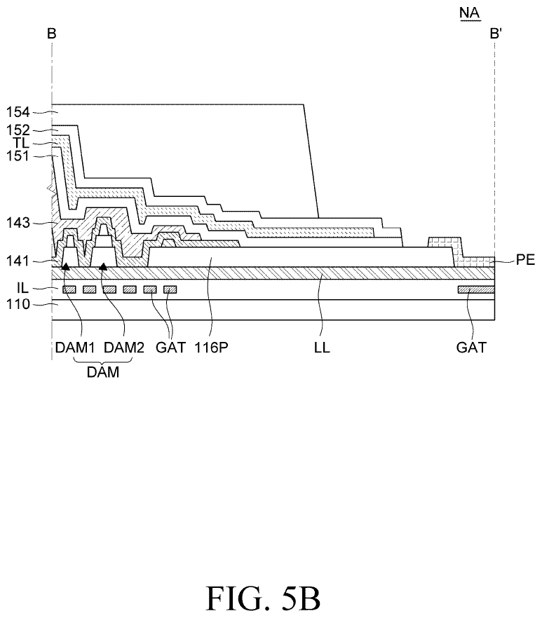

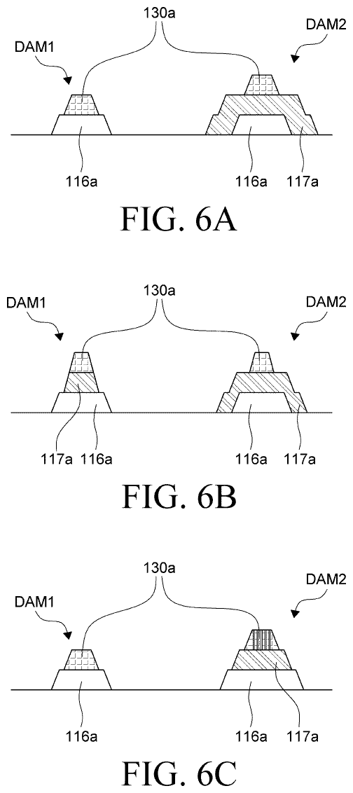

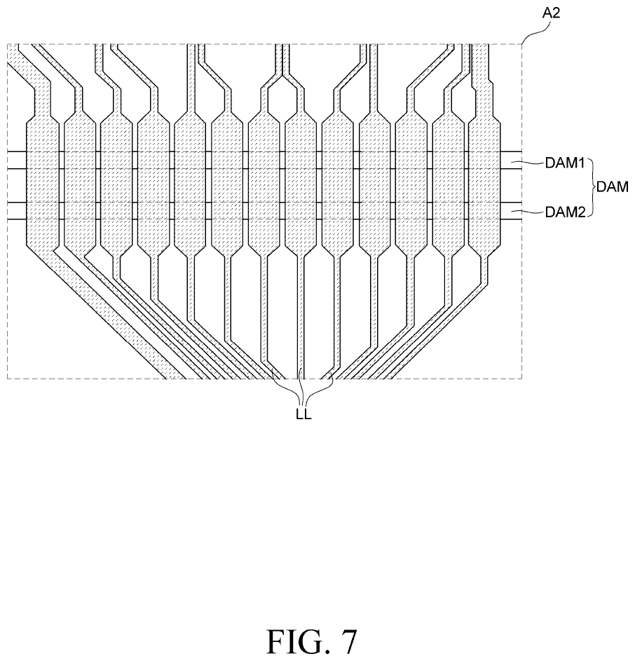

FIG. 2 is a schematic plan view of the display device according to an exemplary embodiment of the present disclosure. FIG. 3 is a cross-sectional view of a sub-pixel of the display device according to an exemplary embodiment of the present disclosure. FIG. 4 is an enlarged plan view of an area A1 of FIG. 2. FIG. 5A is a cross-sectional view taken along line A-A′ of FIG. 2. FIG. 5B is a cross-sectional view taken along line B-B′ of FIG. 2. FIGS. 6A to 6C are schematic cross-sectional views of a dam member of a display device according to an exemplary embodiment of the present disclosure. FIG. 7 is an enlarged plan view of an area A2 of FIG. 2. For convenience of explanation, only a low-potential power line VSSL, a high-potential power line VDDL, a reference line RL, a LOG line LOG, and a data line DL among a plurality of lines are illustrated in FIG. 4.

Referring to FIG. 2, the display panel PN of the display device 100 includes an display area AA and a non-display area NA. The display area AA may be an area where an image is displayed. The plurality of sub-pixels SP may be formed in the display area AA to display an image. The non-display area NA may be an area where an image is not displayed. Various lines and circuits for driving the plurality of sub-pixels SP of the display area AA may be disposed in the non-display area NA. For example, the gate driver GD may be mounted in the non-display area NA, or a pad portion PAD on which a flexible film COF and a printed circuit board PCB are bonded may be disposed in the non-display area NA. In addition, wiring lines for driving the plurality of sub-pixels SP, the gate driver GD, the touch unit 150, or the like may be disposed in the non-display area NA.

A plurality of flexible films COF is connected to the pad portion PAD of the display panel PN. The plurality of flexible films COF may be a film in which various components are disposed on a flexible base film. For example, a driving integrated circuit (IC) may be disposed on the plurality of flexible films COF. The driving IC may be a component that processes data and driving signals for displaying an image. The plurality of flexible films COF may be attached or bonded to a plurality of pad electrodes PE via a conductive adhesive layer, but the embodiments of the present disclosure are not limited thereto.

The printed circuit board PCB is connected to a plurality of flexible films COF. The printed circuit board PCB is electrically connected to the flexible films COF and may be a component that supplies signals to a driving IC. Various components for supplying various signals to the driving ICs may be disposed on the printed circuit board PCB. For example, various components such as the timing controller TC, a power management integrated circuit (PMIC), a memory, or a processor may be disposed on the printed circuit board PCB, but the embodiments of the present disclosure are not limited thereto.

Referring to FIG. 3, the substrate 110 is a support member for supporting other components of the display device 100 and may be made of an insulating material. For example, the substrate 110 may be made of glass, resin, or the like.

The substrate 110 may be formed of one or more layers. For example, the substrate 110 may be formed of a bilayer structure including a first substrate 110a and a second substrate 110b on the first substrate 110a. For example, the first substrate 110a and the second substrate 110b may be formed of polyimide (PI). In addition, although not illustrated in the drawing, an insulating layer may be further disposed between the first substrate 110a and the second substrate 110b.

A multi-buffer layer 111 is disposed on a substrate 110. The multi-buffer layer 111 may reduce the penetration of moisture or impurities through the substrate 110. For example, the multi-buffer layer 111 may be composed of a single layer or a plurality of layers of an insulating material such as silicon nitride (SiNx), silicon oxide (SiOx), and silicon oxynitride (SiON), but is not limited thereto.

A light-shielding layer BSM is disposed on the multi-buffer layer 111. The light-shielding layer BSM may minimize leakage current of a plurality of transistors TR by blocking light incident on an active layer ACT of a transistor TR from the lower portion of the substrate 110. In addition, the light-shielding layer BSM may minimize damage to the plurality of transistors TR caused by charges trapped in the substrate 110. The light-shielding layer BSM may be connected to a source electrode SE or a drain electrode DE of the transistor TR so as to minimize its influence on a threshold voltage of the transistor TR. The light-shielding layer BSM may be formed as a single layer or a plurality of layers made of, for example, one of molybdenum (Mo), copper (Cu), titanium (Ti), aluminum (Al), chromium (Cr), gold (Au), nickel (Ni), and neodymium (Nd), or an alloy thereof, but is not limited thereto.

An active buffer layer 112 is disposed on the light-shielding layer BSM. The active buffer layer 112 may protect the transistor TR from impurities such as alkali ions leaking from the substrate 110. In addition, the active buffer layer 112 may improve adhesion between layers formed above the active buffer layer 112 and the substrate 110. For example, the active buffer layer 112 may be formed of a single layer or a plurality of layers of an insulating material such as silicon nitride (SiNx), silicon oxide (SiOx), and silicon oxynitride (SiON), but is not limited thereto.

The transistor TR is disposed on the active buffer layer 112. The transistor TR includes the active layer ACT, a gate electrode GE, the source electrode SE, and the drain electrode DE.

First, the active layer ACT is disposed on the active buffer layer 112. The active layer ACT may be made of a semiconductor material such as an oxide semiconductor, amorphous silicon, or polysilicon, but is not limited thereto.

A gate insulating layer 113 is disposed on the active layer ACT. The gate insulating layer 113 is an insulating layer for insulating the active layer ACT and the gate electrode GE, and may be composed of a single layer or a plurality of layers of silicon oxide (SiOx) or silicon nitride (SiNx), but is not limited thereto.

The gate electrode GE is disposed on the gate insulating layer 113. The gate electrode GE may be a single layer or a plurality of layers made of a conductive material, for example, one of molybdenum (Mo), aluminum (Al), chromium (Cr), gold (Au), titanium (Ti), nickel (Ni), neodymium (Nd), and copper (Cu), or an alloy thereof, but is not limited thereto.

A first interlayer insulating layer 114 is disposed on the gate electrode GE, and a second interlayer insulating layer 115 is disposed on the first interlayer insulating layer 114. The first interlayer insulating layer 114 and the second interlayer insulating layer 115 are insulating layers for protecting the underlying structure, and may be composed of a single layer or a plurality of layers of silicon oxide (SiOx) or silicon nitride (SiNx), but are not limited thereto.

The source electrode SE and the drain electrode DE are disposed on the second interlayer insulating layer 115. The source electrode SE and the drain electrode DE can be electrically connected to the active layer ACT through contact holes formed in the second interlayer insulating layer 115, the first interlayer insulating layer 114, and the gate insulating layer 113. The source electrode SE and the drain electrode DE may be formed of a single layer or multilayer structure of a conductive material, for example, copper (Cu), aluminum (Al), molybdenum (Mo), nickel (Ni), titanium (Ti), gold (Au), chromium (Cr), or an alloy thereof, but are not limited thereto.

A capacitor Cst is disposed on the gate insulating layer 113. The capacitor Cst may include a first capacitor electrode C1 and a second capacitor electrode C2. The first capacitor electrode C1 may be disposed on the gate insulating layer 113, and the second capacitor electrode C2 may be disposed on the first interlayer insulating layer 114. The first capacitor electrode C1 and the second capacitor electrode C2 may overlap each other with the first interlayer insulating layer 114 interposed therebetween. For example, the first capacitor electrode C1 and the second capacitor electrode C2 may be a single layer or plurality of layers made of any one of molybdenum (Mo), aluminum (Al), chromium (Cr), gold (Au), titanium (Ti), nickel (Ni), neodymium (Nd), and copper (Cu), or an alloy thereof, but is not limited thereto.

Meanwhile, various conductive layers may be further disposed on the substrate 110. The various conductive layers may constitute any one of a plurality of wiring lines, a plurality of transistors TR, and a plurality of capacitors Cst. For example, a first source-drain conductive layer SDL1 and a second source-drain conductive layer SDL2 may be disposed on the second interlayer insulating layer 115. The first source-drain conductive layer SDL1 may be connected to the first capacitor electrode C1, and the second source-drain conductive layer SDL2 may be connected to the second capacitor electrode C2. Each of the first source-drain conductive layer SDL1 and the second source-drain conductive layer SDL2 may function as an electrode that connects the first capacitor electrode C1 and the second capacitor electrode C2 to other components of the sub-pixel SP.

A planarization layer 116 is disposed on the transistor TR. The planarization layer 116 is an insulating layer that planarizes the upper portion of the substrate 110. The planarization layer 116 may be made of an organic material, and may be composed of a single layer or plurality of layers of an organic material such as polyimide or photo acryl, but is not limited thereto.

A light-emitting diode 120 is disposed on the planarization layer 116. The light-emitting diode 120 may be an organic light-emitting diode (OLED). The light-emitting diode 120 includes an anode 121, a light-emitting layer 122, and a cathode 123.

The anode 121 is disposed on the planarization layer 116. The anode 121 may be connected to the drain electrode DE of the transistor TR. The anode 121 may be formed of a conductive material having a high work function to supply holes to the light-emitting layer 122. For example, the anode 121 may be formed of a transparent conductive material such as indium tin oxide (ITO), or indium zinc oxide (IZO), but is not limited thereto.

Meanwhile, the display device 100 may be implemented in a top emission or bottom emission manner. In the case of the top emission manner, a reflective layer may be disposed below the anode 121 to reflect light emitted from the light-emitting layer 122 toward the cathode 123. For example, the reflective layer may include a material with excellent reflectivity, such as aluminum (Al) or silver (Ag), but is not limited thereto. Conversely, in the case of the bottom emission manner, the anode 121 may be formed only of a transparent conductive material. Hereinafter, the display device 100 according to an exemplary embodiment of the present disclosure will be described assuming that the display device 100 is implemented in the top emission manner.

A bank 117 is disposed on the anode 121 and the planarization layer 116. The bank 117 may cover the edge of the anode 121. The bank 117 may partition the plurality of sub-pixels SP and suppress color mixing between the plurality of sub-pixels SP. The bank 117 may be an organic insulating material. For example, the bank 117 may be made of any one of polyimide, acrylic, and benzocyclobutene (BCB)-based resins, but is not limited thereto.

A spacer 130 is disposed on the bank 117. The spacer 130 may suppress damage to the light-emitting diode 120 that may occur when a fine metal mask (FMM) used to form the light-emitting layer 122 of the light-emitting diode 120 directly contacts the bank 117 or the anode 121. The spacer 130 may be made of the same material as the bank 117 or may be made of an insulating material different from the bank 117, but is not limited thereto. In addition, the spacer 130 and the bank 117 may be formed integrally at once. Since the spacer 130 is disposed on the bank 117, the cathode 123 may be disposed to cover the spacer 130 and the bank 117.

The light-emitting layer 122 is disposed on the anode 121 and the bank 117. The light-emitting layer 122 may be an organic layer for emitting light of a specific color. The light-emitting layer 122 may further include various layers such as a hole transport layer, a hole injection layer, a hole blocking layer, an electron injection layer, an electron blocking layer, or an electron transport layer. The light-emitting layer 122 may be separately formed for each sub-pixel SP so that each sub-pixel SP may emit a different color. For example, the light-emitting layer 122 for red, the light-emitting layer 122 for green, and the light-emitting layer 122 for blue may be separately formed for each sub-pixel SP. Meanwhile, the light-emitting layer 122 for emitting white light may be commonly formed for the plurality of sub-pixels SP, and a light conversion member for converting the white light into light of various colors may be separately provided, but the embodiments of the present disclosure are not limited thereto.

The cathode 123 is disposed on the light-emitting layer 122. The cathode 123 may be formed as a single layer across the entire surface of the substrate 110. That is, the cathode 123 may be a common layer formed in common for the plurality of sub-pixels SP. Since the cathode 123 supplies electrons to the light-emitting layer 122, the cathode 123 may be formed of a conductive material having a low work function. The cathode 123 may be formed of, for example, a transparent conductive material such as indium tin oxide (ITO) or indium zinc oxide (IZO), a metal alloy such as MgAg, an ytterbium (Yb) alloy, or the like, and may further include a metal doping layer, but is not limited thereto.

A protective layer 118 is disposed on the cathode 123. The protective layer 118 may protect the light-emitting diode 120 from foreign substances or moisture infiltration. For example, the protective layer 118 may be made of an inorganic material such as aluminum oxide (Al2O3) or silicon nitride (SiNx).

An encapsulation layer 140 is disposed on the protective layer 118. The encapsulation layer 140 may protect the light-emitting diode 120 from moisture or the like penetrating from the outside of the display device 100. The encapsulation layer 140 includes a first inorganic encapsulation layer 141, an organic encapsulation layer 142, and a second inorganic encapsulation layer 143.

The first inorganic encapsulation layer 141 is disposed on the protective layer 118, and the second inorganic encapsulation layer 143 is disposed on the first inorganic encapsulation layer 141. The first inorganic encapsulation layer 141 and the second inorganic encapsulation layer 143 may serve to block the penetration of moisture or oxygen. The first inorganic encapsulation layer 141 and the second inorganic encapsulation layer 143 may be made of an inorganic material, and for example, may be made of an inorganic material such as silicon nitride (SiNx), silicon oxide (SiOx), or aluminum oxide (AlOx), but are not limited thereto.

The organic encapsulation layer 142 is disposed between the first inorganic encapsulation layer 141 and the second inorganic encapsulation layer 143. The organic encapsulation layer 142 may be formed to a thickness thicker than the first inorganic encapsulation layer 141 and the second inorganic encapsulation layer 143 so as to adsorb and block foreign substances (particles) that may occur during the manufacturing process of the display device 100. The organic encapsulation layer 142 may fill cracks that may occur in the first inorganic encapsulation layer 141 and the second inorganic encapsulation layer 143, and cover foreign substances on the first inorganic encapsulation layer 141 to flatten the upper portion. The organic encapsulation layer 142 may be made of an organic material, and may be made of, for example, an epoxy-based polymer or an acrylic-based polymer, but is not limited thereto.

The touch unit 150 is disposed on the encapsulation layer 140. The touch unit 150 may sense an external touch input using a user's finger or a touch pen, or the like. The touch unit 150 includes a touch buffer layer 151, a bridge electrode BE, a touch electrode TE, a touch insulation layer 152, a touch passivation layer 153, and a touch protection layer 154.

First, the touch buffer layer 151 is disposed on the encapsulation layer 140. The touch buffer layer 151 is an insulating layer for protecting peripheral components such as the encapsulation layer 140 and the light-emitting diode 120 during the formation process of the touch unit 150. The touch buffer layer 151 may minimize the penetration of moisture from the outside, materials used in the manufacturing process of the touch unit 150, or the like into the light-emitting diode 120. For example, the touch buffer layer 151 may be made of an insulating material such as silicon oxide (SiOx) or silicon nitride (SiNx), but is not limited thereto.

A plurality of bridge electrodes BE are disposed on a touch buffer layer 151. The plurality of bridge electrodes BE is electrodes made of a bridge metal BM and may connect a plurality of touch electrodes TE to each other. For example, a pair of adjacent touch electrodes TE among the plurality of touch electrodes TE may be electrically connected to each other through the bridge electrodes BE. For example, the plurality of bridge electrodes BE may be formed of a metal material such as copper (Cu), aluminum (Al), titanium (Ti), chromium (Cr), nickel (Ni), or a laminated structure of a metal material such as titanium/aluminum/titanium (Ti/Al/Ti), but is not limited thereto.

The touch insulation layer 152 is disposed on the bridge electrode BE. The touch insulation layer 152 is disposed between the plurality of bridge electrodes BE and the plurality of touch electrodes TE, and may insulate some of the bridge electrodes BE and some of the touch electrodes TE. The touch insulation layer 152 may be made of an insulating material such as silicon oxide (SiOx) or silicon nitride (SiNx), but is not limited thereto.

The plurality of touch electrodes TE is disposed on a touch insulating layer 152. The plurality of touch electrodes TE is electrodes made of a sensor metal SM and are electrodes for sensing a touch input. For example, when the touch unit 150 senses a touch input in a mutual capacitance manner, the plurality of touch electrodes TE may be made of a touch driving electrode to which a touch driving signal is applied and a touch sensing electrode that forms a capacitance with the touch driving electrode. In addition, the touch input may be sensed based on a change in capacitance between the touch driving electrode and the touch sensing electrode.

However, the touch sensing method of the touch unit 150 is exemplary, and the touch unit 150 may sense touch input using a self-capacitance method, but is not limited thereto.

The touch passivation layer 153 is disposed on the plurality of touch electrodes TE. The touch passivation layer 153 is an insulating layer for protecting the plurality of touch electrodes TE and the plurality of bridge electrodes BE, and can suppress corrosion of the plurality of touch electrodes TE and the plurality of bridge electrodes BE caused by external moisture, or the like. For example, the touch passivation layer 153 may be made of an insulating material such as silicon oxide (SiOx) or silicon nitride (SiNx), but is not limited thereto.

The touch protection layer 154 is disposed on the touch passivation layer 153. The touch protection layer 154 may protect the plurality of touch electrodes TE and the plurality of bridge electrodes BE from external moisture or impact together with the touch passivation layer 153. For example, the touch protection layer 154 may be made of an organic material such as an epoxy-based or acrylic-based polymer, but is not limited thereto.

Meanwhile, in the drawing, the touch passivation layer 153 is depicted as being disposed below the touch protection layer 154, but the touch passivation layer 153 may also be formed on the touch protection layer 154, and is not limited thereto.

Referring to FIG. 4, the pad portion PAD and the plurality of wiring lines are disposed in the non-display area NA.

The pad portion PAD is a portion electrically connected to a plurality of flexible films COF, and may include a plurality of pad electrodes PE and a plurality of touch pad electrodes TPE. Each of the plurality of pad electrodes PE may transmit signals from the printed circuit board PCB and the flexible film COF to various wiring lines of the display panel PN. In addition, the plurality of touch pad electrodes TPE may transmit signals from the printed circuit board PCB and the flexible film COF to the touch line TL of a touch unit 150. The pad portion PAD may be exposed from the encapsulation layer 140 for connection with the flexible film COF. The pad portion PAD may be disposed on the outside of the encapsulation layer 140.

Wiring lines related to driving the display device 100, that is, image display, are disposed in the non-display area NA. For example, a plurality of low-potential power lines VSSL, a LOG (Line On Glass) line LOG, a plurality of high-potential power lines VDDL, a plurality of reference lines RL, and a plurality of data lines DL may be disposed in the non-display area NA.

The plurality of low-potential power lines VSSL is disposed in the non-display area NA. The plurality of low-potential power lines VSSL is lines for applying a low-potential power voltage to the plurality of sub-pixels SP. Some of the plurality of low-potential power lines VSSL extending from the pad portion PAD may extend in a form that encloses the periphery of the display area AA. In addition, other of the plurality of low-potential power lines VSSL extending from the pad portion PAD may be disposed to cover the data lines DL, thereby functioning as a protective film to suppress influences of the data lines DL on other lines.

The plurality of high-potential power lines VDDL is disposed in the non-display area NA. The plurality of high-potential power lines VDDL is wiring lines for applying a high-potential power voltage to the plurality of sub-pixels SP. The shorting-bar-shaped high-potential power line VDDL extending in a first direction D1 between the display area AA and the pad portion PAD is disposed. Moreover, the plurality of high-potential power lines VDDL extending in a second direction D2 from the pad portion PAD may be connected to the shorting-bar-shaped high-potential power line VDDL. In this case, a portion of the plurality of high-potential power lines VDDL extending in the second direction D2 from the pad portion PAD may be disposed between the plurality of low-potential power lines VSSL. Therefore, by forming the shorting bar-shaped high-potential power line VDDL that connects the plurality of high-potential power lines VDDL in the non-display area NA, the resistance deviation between the plurality of high-potential power lines VDDL can be reduced and the brightness uniformity can be improved.

In the non-display area NA, the reference line RL is disposed between the high-potential power line VDDL and the low-potential power line VSSL. A shorting-bar-shaped reference line RL extending in the first direction D1 between the display area AA and the pad portion PAD may be disposed, and a plurality of reference lines RL extending in a second direction D2 from the pad portion PAD may be connected to the shorting-bar-shaped reference line RL. At this time, the high-potential power line VDDL on the same layer as the reference line RL is disposed between the shorting-bar-shaped reference line RL and the reference line RL connected to the pad portion PAD. Accordingly, at the point where the reference line RL and the high-potential power line VDDL intersect each other, an auxiliary reference line RLa located on a different layer from the high-potential power line VDDL may be used to connect the shorting-bar-shaped reference line RL and the reference line RL connected to the pad portion PAD. Therefore, by forming the shorting-bar-shaped reference line RL that connects the plurality of reference lines RL in the non-display area NA, the resistance deviation between the plurality of reference lines RL can be reduced and the brightness uniformity can be improved.

In the non-display area NA, the LOG line LOG is disposed between the low-potential power line VSSL and the high-potential power line VDDL. The LOG line LOG is a wiring line for transmitting various signals to the gate driver GD. For example, the gate driver GD is mounted in the non-display area NA, and the LOG line LOG extends from the pad portion PAD to the gate driver GD to transmit various signals to the gate driver GD.

The plurality of data lines DL may be disposed to extend from the pad portion PAD. The plurality of data lines DL may be disposed to radially extend from the pad portion PAD. The plurality of data lines DL may extend from the pad portion PAD to the display area AA, thereby transmitting the data voltage Vdata to the plurality of sub-pixels SP of the display area AA.

Meanwhile, a multiplexer circuit MUX, an electrostatic discharge protection circuit ESD, and a light inspection transistor AP may be further disposed between the shorting-bar-shaped reference line RL and the display area AA. The multiplexer circuit MUX is a circuit for distributing a signal to the plurality of wiring lines, and the output of each wiring line may be controlled using the multiplexer circuit MUX. The electrostatic discharge protection circuit ESD may protect the internal configuration of the display device 100 by discharging static electricity introduced from the outside. When checking whether the light-emitting diode 120 is turned on in the manufacturing process of the display device 100, a signal may be temporarily applied to the light-emitting diode 120 using the light inspection transistor AP.

Meanwhile, the wiring lines disposed between the pad portion PAD and the display area AA may also be referred to as link lines LL. That is, some of the wiring lines disposed in the non-display area NA may be defined as the link lines LL. For example, in order to distinguish between some of the data lines DL disposed in the display area AA and the remainder of the data lines DL disposed in the non-display area NA, the remainder of the data lines DL disposed in the non-display area NA may be referred to as data link lines LL. Similarly, some of the high-potential power lines VDDL, low-potential power lines VSSL, and reference lines RL disposed in the non-display area NA may also be referred to as high-potential power link lines LL, low-potential power link lines LL, reference link lines LL, or the like. Therefore, the following description will assume that the link lines LL define some of the wiring lines disposed in the non-display area NA.

Next, referring to FIG. 3 and FIG. 5A together, some configurations of the display area AA may be disposed to extend to the non-display area NA.

Meanwhile, in FIG. 5A, for convenience of explanation, the multi-buffer layer 111, the active buffer layer 112, the gate insulating layer 113, the first interlayer insulating layer 114, and the second interlayer insulating layer 115 are briefly represented as an insulating layer group IL. However, in reality, the multi-buffer layer 111, the active buffer layer 112, the gate insulating layer 113, the first interlayer insulating layer 114, and the second interlayer insulating layer 115 may be disposed between the substrate 110 and the low-potential power line VSSL.

The encapsulation layer 140 may be disposed to cover the entire display area AA and a portion of the non-display area NA extending from the display area AA. For example, the organic encapsulation layer 142 of the encapsulation layer 140 may be disposed from the display area AA to the area before a dam member DAM of the non-display area NA. Moreover, the first inorganic encapsulation layer 141 and the second inorganic encapsulation layer 143 may extend to an area outside the dam member DAM. The first inorganic encapsulation layer 141 and the second inorganic encapsulation layer 143 extending to the area outside the dam member DAM may be in contact with each other to seal the organic encapsulation layer 142.

Meanwhile, the second inorganic encapsulation layer 143 may be disposed to cover the entire first inorganic encapsulation layer 141 in at least a portion of the non-display area NA. The second inorganic encapsulation layer 143 may cover the edge of the first inorganic encapsulation layer 141, thereby minimizing lifting of the first inorganic encapsulation layer 141.

Organic insulating layers made of organic materials, such as the bank 117 and the planarization layer 116, are relatively vulnerable to moisture penetration compared to inorganic insulating layers. Therefore, the edges of the bank 117 and the planarization layer 116 may be disposed in the area inside the encapsulation layer 140. For example, the edges of the bank 117 and the planarization layer 116 may be disposed in the area inside the encapsulation layer 140 and may be disposed on the low-potential power line VSSL.

At least some of the plurality of insulating layers of the touch unit 150 may be disposed to extend from the display area AA to the non-display area NA. For example, the touch buffer layer 151, the touch insulating layer 152, or the like may extend to the outside of the encapsulation layer 140 and cover the edge of the encapsulation layer 140. For example, the touch passivation layer 153 may extend from the display area AA to the area inside the dam member DAM. For example, the touch protection layer 154 may extend from the display area AA to the area outside the dam member DAM. However, the touch protection layer 154 may be disposed only in the area overlapping the organic encapsulation layer 142, but is not limited thereto.

Moreover, a touch active area TAA where the touch electrode TE is disposed may be disposed from the display area AA to a part of the non-display area NA. In the touch active area TAA, the touch electrode TE and the bridge electrode BE are disposed to sense a touch input. The touch active area TAA may be formed to be larger than the display area AA.

A ground line GND and a pseudo line PS may be further disposed outside the touch active area TAA within the non-display area NA, that is, in the area where touch input is not sensed. The ground line GND and the pseudo line PS may reduce noise such as electromagnetic interference and improve touch performance, and a more detailed description thereof will be provided later.

A plurality of crack suppression patterns CSP is disposed in the non-display area NA. When manufacturing the display device 100, a configuration of the display device 100 is formed on a mother substrate, and the mother substrate may be cut into a plurality of pieces to manufacture the plurality of display devices 100. However, when cutting the mother substrate, cracks may occur in the substrate 110 or the configuration on the substrate 110 at the edge portion of the substrate 110 due to impact. The plurality of crack suppression patterns CSP are disposed along the edge of the substrate 110 and may suppress propagation of cracks into the display device 100. The plurality of crack suppression patterns CSP may be formed by patterning some of a plurality of insulating layers on the substrate 110. For example, the plurality of crack suppression patterns CSP may be formed of a multi-layer structure of an organic insulating layer and an inorganic insulating layer, but are not limited thereto.

The dam member DAM is disposed outside the organic encapsulation layer 142 in the non-display area NA. The dam member DAM is configured to suppress the overflow of the organic encapsulation layer 142 of the encapsulation layer 140. The dam member DAM may be disposed to enclose the display area AA. The dam member DAM may be disposed to enclose the organic encapsulation layer 142 of the encapsulation layer 140. The dam member DAM may be formed in a closed loop shape enclosing the display area AA and the organic encapsulation layer 142. The dam member DAM may be disposed on the low-potential power line VSSL while enclosing the organic encapsulation layer 142.

The dam member DAM may include a first dam member DAM1 and a second dam member DAM2. The first dam member DAM1 may be disposed between the second dam member DAM2 and the organic encapsulation layer 142. The first dam member DAM1 and the second dam member DAM2 may be formed from various insulating layers among the plurality of insulating layers on the substrate 110.

For example, referring to FIG. 6A, the first dam member DAM1 may be formed of a planarization layer pattern 116a made of the same material as the planarization layer 116 and a spacer pattern 130a made of the same material as the spacer 130. The second dam member DAM2 may be formed of the planarization layer pattern 116a, a bank pattern 117a made of the same material as the bank 117, and the spacer pattern 130a.

Referring to FIG. 6B, each of the first dam member DAM1 and the second dam member DAM2 may be formed of the planarization layer pattern 116a, the bank pattern 117a, and the spacer pattern 130a. The bank pattern 117a of the second dam member DAM2 may be disposed to cover a side surface of the planarization layer pattern 116a.

Referring to FIG. 6C, the first dam member DAM1 may be formed of the planarization layer pattern 116a and the spacer pattern 130a, and the second dam member DAM2 may be formed of the planarization layer pattern 116a, the bank pattern 117a, and the spacer pattern 130a. In this case, the spacer pattern 130a of the second dam member DAM2 may be formed of a plurality of slit patterns.

Therefore, the dam member DAM may be composed of a combination of various insulation layers as illustrated in FIGS. 6A to 6C.

Next, referring to FIG. 5B, a pad electrode PE is disposed in the non-display area NA. The pad electrode PE may transmit signals from the flexible film COF and the printed circuit board PCB to a link line LL and a wiring line. For example, the link line LL is disposed on an insulating layer group IL in the non-display area NA, and the pad electrode PE is disposed on the link line LL. The link line LL may transmit the signal from the pad electrode PE to the wiring line in the display area AA.

A plurality of gate conductive layers GAT may be disposed between the insulating layer groups IL in the non-display area NA. The plurality of gate conductive layers GAT may be included in various configuration, and for example, may configure the link line LL, gate driver GD, or the like.

A planarization layer dam 116P is disposed between the pad electrode PE and the dam member DAM in the non-display area NA. Since the planarization layer dam 116P is disposed to be spaced apart from the planarization layer 116 of the display area AA, it is possible to suppress the penetration of moisture into the display area AA through the planarization layer dam 116P. In addition, the planarization layer dam 116P may compensate for the step of the dam member DAM, thereby minimizing disconnection of the touch line TL or the like due to the step.

And referring to FIG. 2 and FIG. 7 together, the dam member DAM is configured in a closed loop shape enclosing the display area AA, so that at least some of the wiring lines extending from the pad portion PAD to the display area AA may intersect the dam member DAM. In particular, after the dam member DAM is formed, the encapsulation layer 140 and the touch unit 150 may be formed. Moreover, the wiring lines of the touch unit 150, for example, the link line LL functioning as the touch line TL, the pseudo line PS, and the ground line GND, may pass through the dam member DAM. In this case, the link line LL passing through the dam member DAM may be easily disconnected due to the step of the dam member DAM. Therefore, the width of the link line LL overlapping the dam member DAM may be formed wide to suppress the disconnection of the link line LL in the dam member DAM.

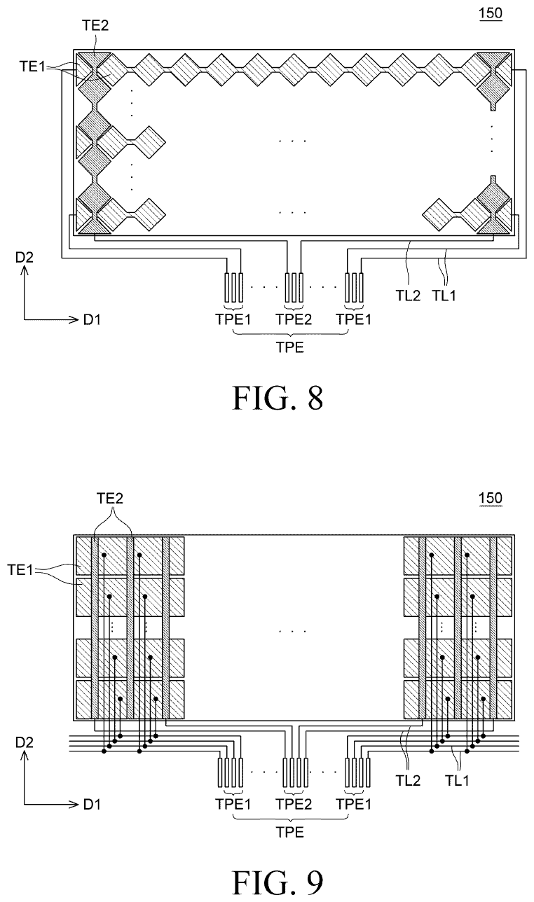

Hereinafter, the touch unit 150 of the display device 100 according to an exemplary embodiment of the present disclosure will be described in more detail with reference to FIGS. 8 to 23B.

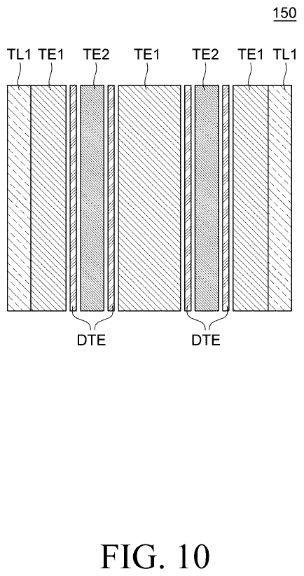

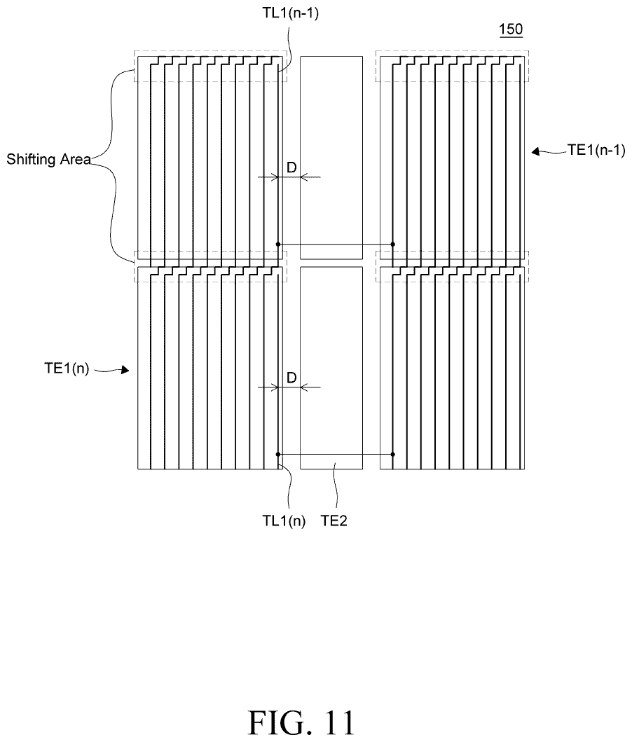

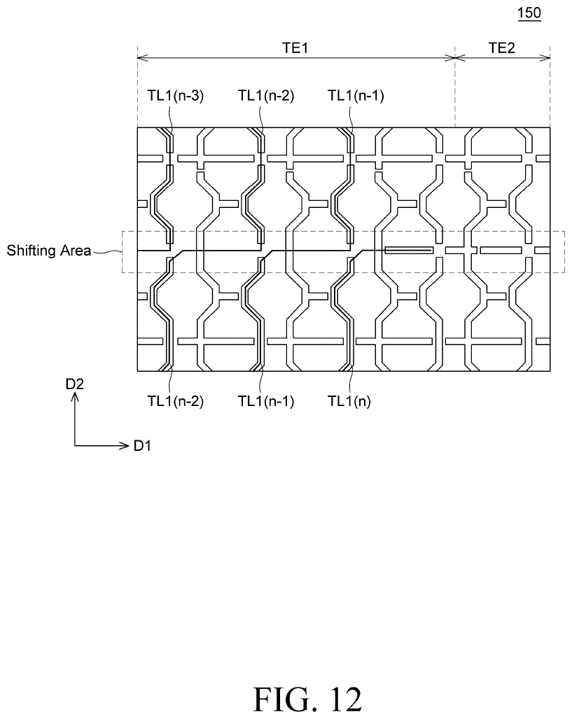

FIGS. 8 and 9 are schematic plan views of the touch unit of the display device according to an exemplary embodiment of the present disclosure. FIG. 10 is a schematic enlarged plan view of the touch unit of the display device according to an exemplary embodiment of the present disclosure. FIGS. 11 and 12 are schematic enlarged plan views of the touch unit of the display device according to an exemplary embodiment of the present disclosure.

First, the touch unit 150 may sense touch input using a mutual-capacitance method and/or a self-capacitance method. The mutual-capacitance method is a method of sensing touch input based on a change in capacitance between a touch driving electrode and a touch sensing electrode. The self-capacitance method is a method of sensing touch input based on a change in capacitance between an external input and a touch electrode.

Hereinafter, it will be explained assuming that the touch unit 150 of the display device 100 according to an exemplary embodiment of the present disclosure is the touch unit 150 that uses the mutual-capacitance method and the self-capacitance method in combination.

Referring to FIGS. 8 and 9, the touch unit 150 includes a plurality of touch lines TL and a plurality of touch electrodes TE. The plurality of touch lines TL includes a plurality of first touch lines TL1 and a plurality of second touch lines TL2, and the plurality of touch electrodes TE includes a plurality of first touch electrodes TE1 and a plurality of second touch electrodes TE2. In this case, as illustrated in FIGS. 8 and 9, the shape and disposition of the plurality of touch electrodes TE of the touch unit 150 and the connection structure of the touch electrodes TE and the touch lines TL may be configured in various ways.

For example, referring to FIG. 8, the plurality of first touch electrodes TE1 may be disposed in a matrix form with a predetermined interval. Each of the plurality of first touch electrodes TE1 may be formed in a diamond shape. In addition, among the plurality of first touch electrodes TE1, the first touch electrodes TE1 of the same line disposed along the first direction D1 may be connected to each other. For example, the first touch electrodes TE1 of the nth row may be electrically connected to each other to form a line of one first touch electrode TE1.

The plurality of second touch electrodes TE2 may be disposed in a matrix form with a predetermined interval. Each of the plurality of second touch electrodes TE2 may be formed in a diamond shape. The plurality of second touch electrodes TE2 may be disposed to be staggered with the plurality of first touch electrodes TE1. Among the plurality of second touch electrodes TE2, second touch electrodes TE2 in the same line disposed along the second direction D2 may be connected. For example, the second touch electrodes TE2 in the nth column may be electrically connected to each other to form a line of one second touch electrode TE2. Accordingly, the line of the first touch electrode TE1 and the line of the second touch electrode TE2 may intersect each other.

The plurality of first touch lines TL1 are electrically connected to the plurality of first touch electrodes TE1. The plurality of first touch lines TL1 is electrically connected to a first touch pad electrode TPE1 among the plurality of touch pad electrodes TPE, and may transmit the touch signal from the first touch pad electrode TPE1 to the plurality of first touch electrodes TE1. For example, the first touch lines TL1 may be connected to both ends of a line of one first touch electrode TE1 composed of the plurality of first touch electrodes TE1 disposed in the same row. By supplying a touch signal to both ends of the line of the first touch electrode TE1, a signal delay can be minimized.

Th plurality of second touch lines TL2 is electrically connected to the plurality of second touch electrodes TE2. The plurality of second touch lines TL2 is electrically connected to a second touch pad electrode TPE2 among the plurality of touch pad electrodes TPE, and the second touch pad electrode TPE2 and the plurality of second touch electrodes TE2 can be electrically connected to each other. For example, the second touch line TL2 may be connected to one end of a line of the second touch electrode TE2 composed of the plurality of second touch electrodes TE2 disposed in the same row.

The touch unit 150 of FIG. 8 may be configured with a dual-feeding structure that concurrently applies signals to both ends of the line of the touch electrodes TE. For example, as the size of the display device 100 increases, the length of the line of touch electrodes TE formed by the same line of touch electrodes TE increases, and signal transmission may be delayed depending on the position of the touch electrodes TE. Accordingly, in order to reduce the time deviation of transmitting and receiving a touch signal, one or more touch lines TL may be connected to the same line constituting the line of touch electrodes TE to minimize the signal delay.

Next, referring to FIG. 9, the plurality of first touch electrodes TE1 may be disposed in a matrix form with a predetermined interval. Each of the plurality of first touch electrodes TE1 may have a rectangular shape. Among the plurality of first touch electrodes TE1, the first touch electrodes TE1 of the same line disposed along the first direction D1 may receive a signal at the same time. For example, a plurality of first touch pad electrodes TPE1 is disposed in the non-display area NA, and an nth first touch line TL1 electrically connected to an nth first touch pad electrode TPE1 of the plurality of first touch pad electrodes TPE1 may be connected to the plurality of first touch electrodes TE1 disposed in the same line.

The plurality of second touch electrodes TE2 may be disposed between the plurality of first touch electrodes TE1. Each of the plurality of second touch electrodes TE2 may have a rectangular shape. For example, the plurality of first touch electrodes TE1 and the plurality of second touch electrodes TE2 may be disposed alternately in the first direction D1. The first touch electrodes TE1 and the second touch electrodes TE2 may be disposed in the same row, and the first touch electrodes TE1 and the second touch electrodes TE2 may be disposed in different columns. Among the plurality of second touch electrodes TE2, the second touch electrodes TE2 in the same line disposed along the second direction D2 may receive a signal at the same time. For example, the plurality of second touch pad electrodes TPE2 are disposed in the non-display area NA, and an nth second touch line TL2 electrically connected to an nth second touch pad electrode TPE2 among the plurality of second touch pad electrodes TPE2 may be connected to the plurality of second touch electrodes TE2 disposed on the same line.

The plurality of first touch lines TL1 is electrically connected to the plurality of first touch electrodes TE1. The plurality of first touch lines TL1 is electrically connected to the first touch pad electrode TPE1 among the plurality of touch pad electrodes TPE, and may transmit the touch signal from the first touch pad electrode TPE1 to the plurality of first touch electrodes TE1.

The plurality of second touch lines TL2 is electrically connected to the plurality of second touch electrodes TE2. The plurality of second touch lines TL2 may be electrically connected to the second touch pad electrode TPE2 among the plurality of touch pad electrodes TPE, and the second touch pad electrode TPE2 and the plurality of second touch electrodes TE2 may be electrically connected to each other.

Meanwhile, the touch unit 150 of FIG. 9 may be configured with a multi-feeding structure that concurrently applies signals to the plurality of touch electrodes TE. For example, as the size of the display device 100 increases, the length of the line of touch electrodes TE formed by the touch electrodes TE of the same line may increase, and signal transmission may be delayed depending on the position of the touch electrodes TE. Accordingly, in order to reduce the time deviation of transmitting and receiving the touch signals, the touch line TL may be connected to each of the plurality of touch electrodes TE of the same line that constitutes the line of touch electrodes TE so that signals may be concurrently applied. Accordingly, by connecting the plurality of touch lines TL one-to-one to each of the plurality of touch electrodes TE, the delay of the touch signal may be reduced, and the touch performance for the entire area of the display device 100 may be improved.

Moreover, the plurality of first touch electrodes TE1 may be touch driving electrodes, and the plurality of second touch electrodes TE2 may be touch sensing electrodes. Furthermore, the plurality of first touch lines TL1 may be touch driving lines, and the plurality of second touch lines TL2 may be touch sensing lines. In this case, the touch driver TD may transmit the touch driving signal to the first touch electrode TE1 through the first touch line TL1, and receive the touch sensing signal from the second touch electrode TE2 through the second touch line TL2.

However, the first touch electrode TE1 and the first touch line TL1 may each be the touch sensing electrode and the touch sensing line, and the second touch electrode TE2 and the second touch line TL2 may each be a touch driving electrode and a touch driving line, and the embodiments of the present disclosure are not limited thereto.

Referring to FIG. 10, the plurality of touch electrodes TE may further include a plurality of dummy touch electrodes DTE. The dummy touch electrodes DTE may be disposed between the plurality of first touch electrodes TE1 and the plurality of second touch electrodes TE2. For example, the dummy touch electrode DTE may be disposed between the first touch electrodes TE1 and the second touch electrodes TE2. For example, the plurality of touch electrodes TE and the plurality of dummy touch electrodes DTE may be disposed at equal intervals. By disposing the dummy touch electrodes DTE, the distance between the first touch electrodes TE1 and the second touch electrodes TE2 may be secured, and the initial capacitance value between the first touch electrodes TE1 and the second touch electrodes TE2 may be reduced.

The touch input may be sensed by sensing the capacitance between the first touch electrode TE1 and the second touch electrode TE2. In this case, as the first touch electrode TE1 and the second touch electrode TE2 get closer, the initial capacitance value between the first touch electrode TE1 and the second touch electrode TE2 may increase, making it somewhat difficult to sense the capacitance change.

For example, when the first touch electrode TE1 and the second touch electrode TE2 are disposed at a first interval without the dummy touch electrode DTE, it can be assumed that the initial capacitance value between the first touch electrode TE1 and the second touch electrode TE2 is 100, and the amount of capacitance change upon touch input is 10. In this case, the difference between the initial capacitance value of 100 and the capacitance value after touch input of 110 is small, so it may be somewhat difficult to detect the touch.

Moreover, when the dummy touch electrode DTE is formed between the first touch electrode TE1 and the second touch electrode TE2, the gap between the first touch electrode TE1 and the second touch electrode TE2 increases. Accordingly, the initial capacitance value between the first touch electrode TE1 and the second touch electrode TE2 may decrease. For example, when the dummy touch electrode DTE is disposed between the first touch electrode TE1 and the second touch electrode TE2, the gap between the first touch electrode TE1 and the second touch electrode TE2 may increase by the first gap and the width of the dummy touch electrode DTE. Accordingly, the initial capacitance value may decrease to a value less than 100, for example, 50. In this case, when the amount of capacitance change during touch input is 10, the difference between the initial capacitance value of 50 and the capacitance value after touch input of 60 is relatively large, so that the touch can be easily detected.

Accordingly, by placing the dummy touch electrode DTE between the first touch electrode TE1 and the second touch electrode TE2, the gap between the first touch electrode TE1 and the second touch electrode TE2 may be secured, and the initial capacitance value between the first touch electrode TE1 and the second touch electrode TE2 may be lowered. Therefore, it is possible to improve the performance of the touch unit 150.

Next, referring to FIGS. 9 and 11, in the touch unit 150 of the multi-feeding structure, the plurality of first touch lines TL1 is disposed around the plurality of second touch electrodes TE2, and parasitic capacitance may be formed between the plurality of first touch lines TL1 and the second touch electrodes TE2. However, when the parasitic capacitance variation occurs between the plurality of first touch lines TL1 and the second touch electrodes TE2, the touch performance may be degraded. Therefore, in the display device 100 according to an exemplary embodiment of the present disclosure, a gap D between the second touch electrodes TE2 and the first touch lines TL1 may be uniformly formed, thereby minimizing the parasitic capacitance variation.

Specifically, the plurality of first touch lines TL1 may extend in the second direction D2 and be electrically connected to the plurality of first touch electrodes TE1 through contact holes. In this case, by shifting the first touch lines TL1 by one line in the first direction D1, a distance D between the contact holes through which the first touch electrodes TE1 and the first touch lines TL1 are connected and the second touch electrodes TE2 may be configured to be constant.

First, an area between the plurality of first touch electrodes TE1 in the second direction D2, for example, an area between the first touch electrode TE1(n) of the nth row and the first touch electrode TE1(n−1) of the n−1th row and an area between the first touch electrode TE1(n) of the nth row and the first touch electrode TE1(n+1) of the n+1th row may be defined as a shifting area in which the first touch line TL1 shifts.

In the nth row, the nth first touch line TL1(n) may be disposed closest to the second touch electrode TE2. In the nth row, the contact hole through which the nth first touch line TL1(n) and the first touch electrode TE1(n) are connected and the second touch electrode TE2 may be disposed to be spaced apart from each other with the gap D.

In addition, the contact hole of the first touch electrode TE1(n) and the first touch line TL1(n) located on the right side of the second touch electrode TE2 and the contact hole of the first touch electrode TE1(n) and the first touch line TL1(n) located on the left side of the second touch electrode TE2 may be disposed symmetrically with respect to the second touch electrode TE2.

Moreover, the first touch line TL1(n) of the nth row for transmitting a signal to the first touch electrode TE1(n) of the nth row is electrically connected to the nth first touch electrode TE1(n). Accordingly, the first touch line TL1(n) is located only up to the shifting area between the nth first touch electrode TE1(n) and the n−1th first touch electrode TE1(n−1), and does not extend to the area of the n−1th first touch electrode TE1(n−1).

Moreover, first, the first touch line TL1 to the (n−1)th first touch line TL1(n−1) may be shifted in the first direction D1 in the shifting area and extended again onto the (n−1)th first touch electrode TE1(n−1). In the (n−1)th row, the (n−1)th first touch line TL1(n−1) may be electrically connected to the first touch electrode TE1(n−1). Moreover, in the (n−1)th row, the contact hole through which the (n−1)th first touch line TL1(n−1) and the first touch electrode TE1(n−1) are connected and the second touch electrode TE2 may be disposed spaced apart from each other by the gap D.

Accordingly, by shifting the remaining first touch lines TL1 except for the nth first touch line TL1(n) connected to the nth first touch electrode TE1(n) in the shifting area and extending them in the second direction D2, the gap D between the contact hole connecting the first touch electrode TE1 and the first touch line TL1 and the second touch electrode TE2 may be configured to be the same.

Meanwhile, the plurality of touch electrodes TE may have a plate-shaped structure as illustrated in FIG. 11, but the plurality of touch electrodes TE may also be formed in a mesh structure as illustrated in FIG. 12. Even when the plurality of touch electrodes TE is formed in a mesh structure as illustrated in FIG. 12, a shifting area may be formed.

Referring to FIG. 12, the plurality of touch electrodes TE may be formed in a mesh structure, and openings of the mesh structure may overlap each of the plurality of sub-pixels SP. The metal of the plurality of touch electrodes TE may be disposed in an area between the plurality of sub-pixels SP. For example, the metal of the plurality of touch electrodes TE may be disposed in an octagonal shape in an area between the sub-pixels SP.

The first touch line TL1 may extend in a second direction D2 along the metal forming the first touch electrode TE1. The first touch line TL1 may be electrically connected to the metal of the first touch electrode TE1 through a contact hole in an area of a first gap with the second touch electrode TE2. In addition, the plurality of first touch lines TL1 may be shifted in the first direction D1 in a shifting area and then extend upward again.

Accordingly, the shifting area can be formed in the touch unit 150 of various structures, thereby forming a constant gap between the contact hole where the first touch electrode TE1 and the first touch line TL1 are connected and the second touch electrode TE2.

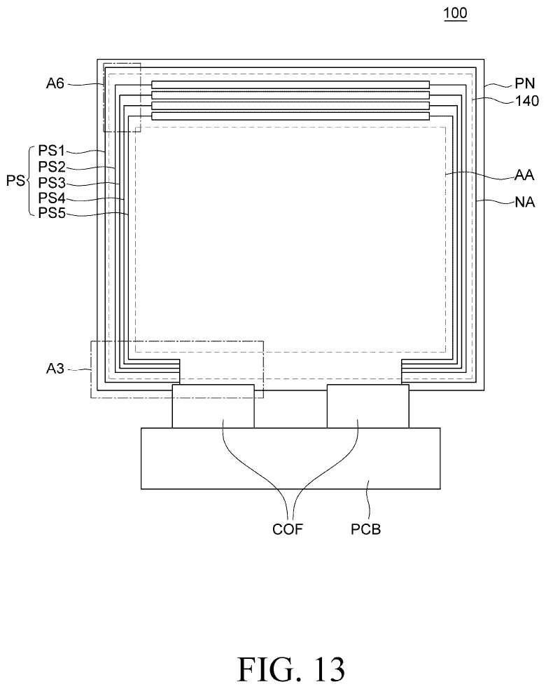

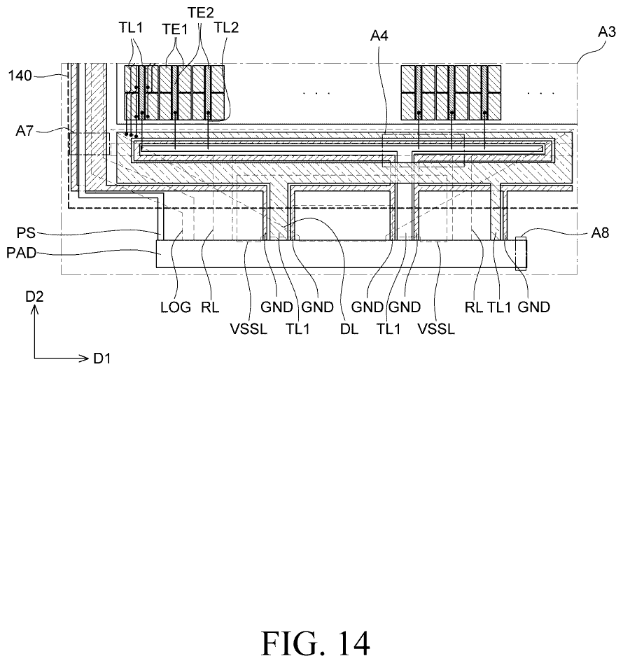

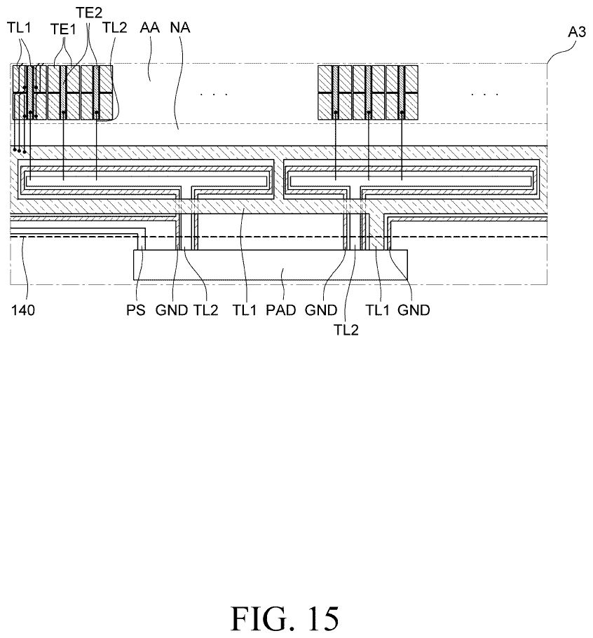

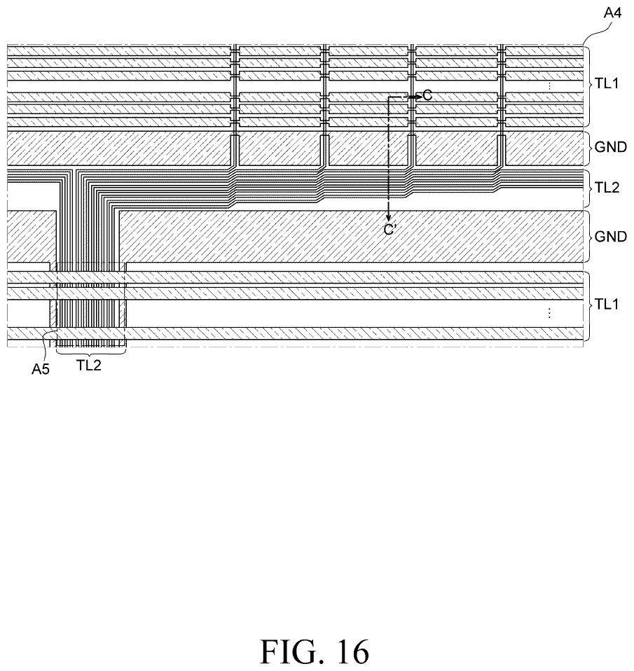

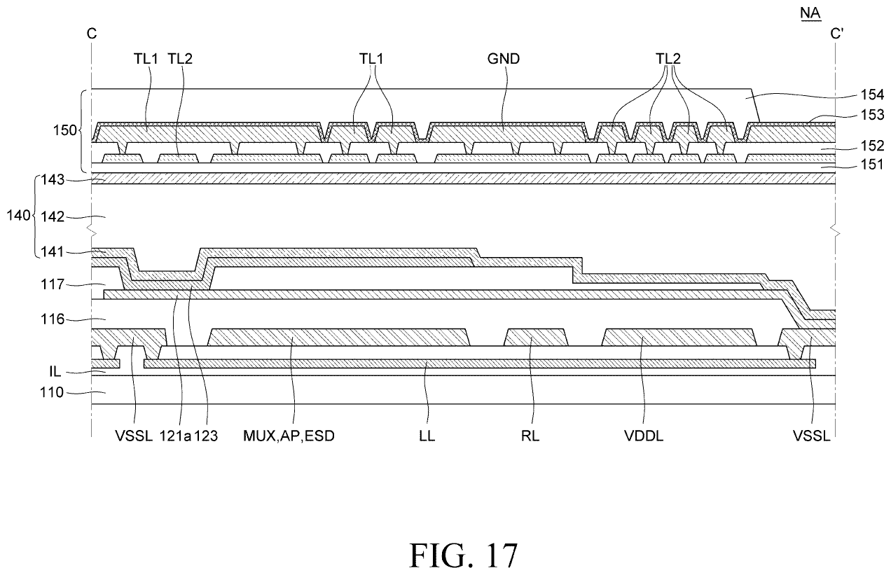

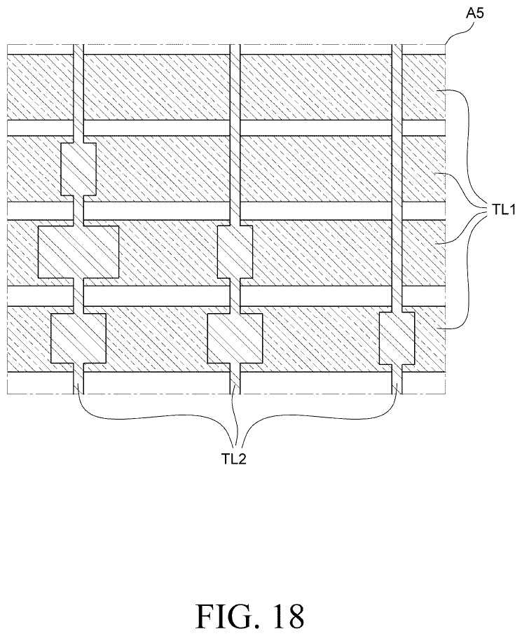

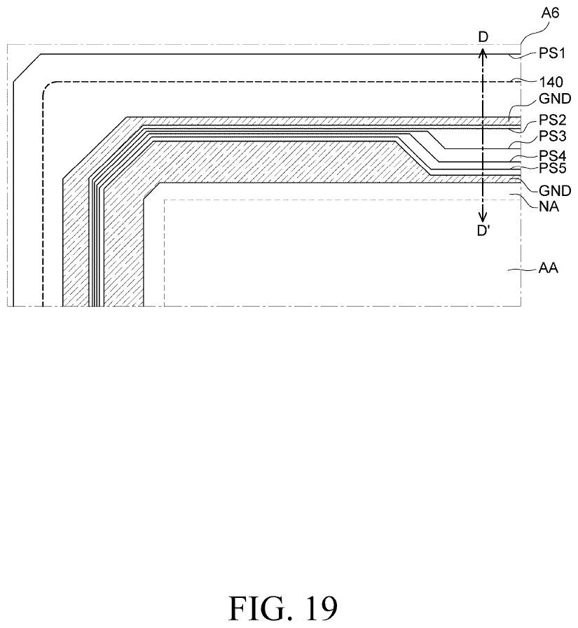

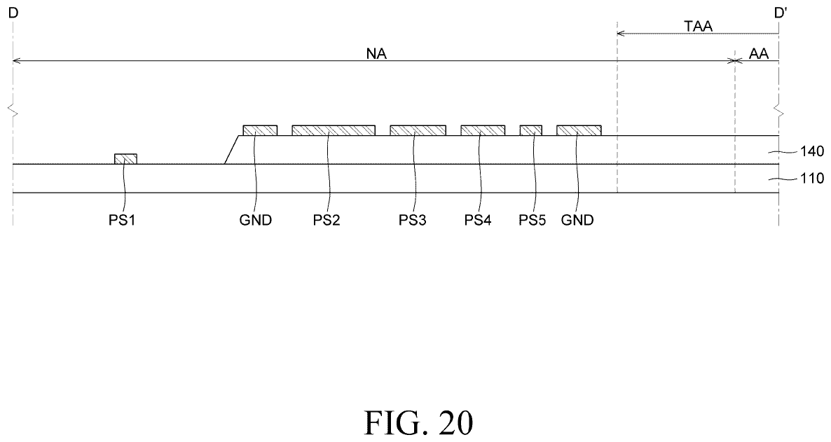

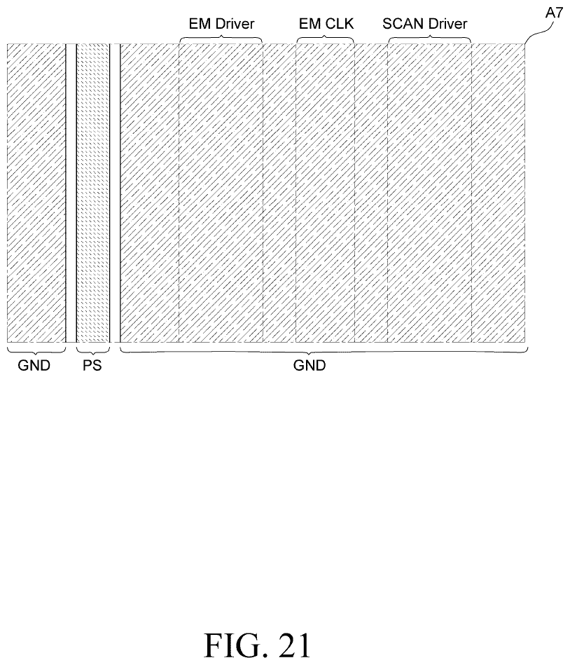

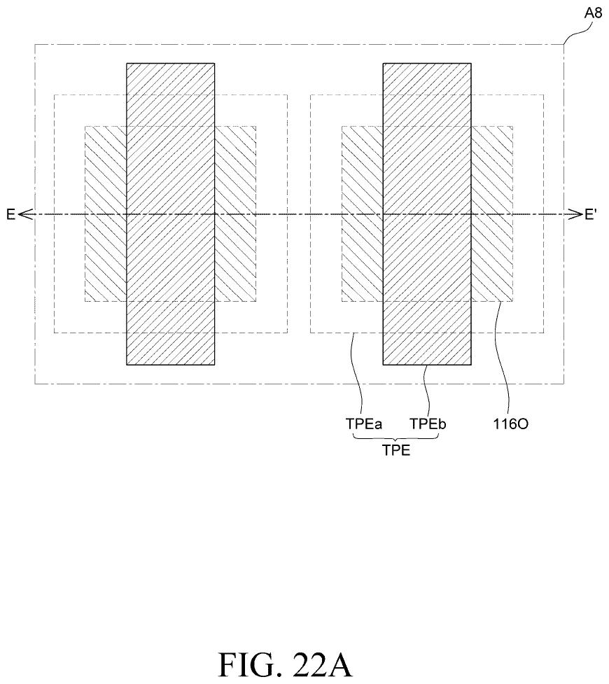

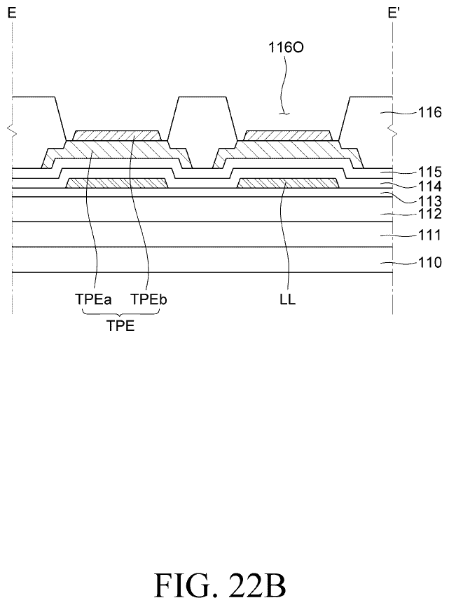

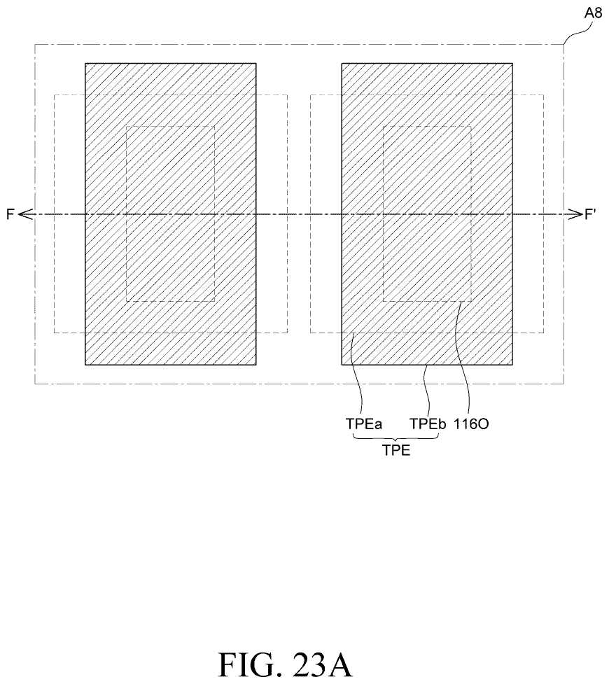

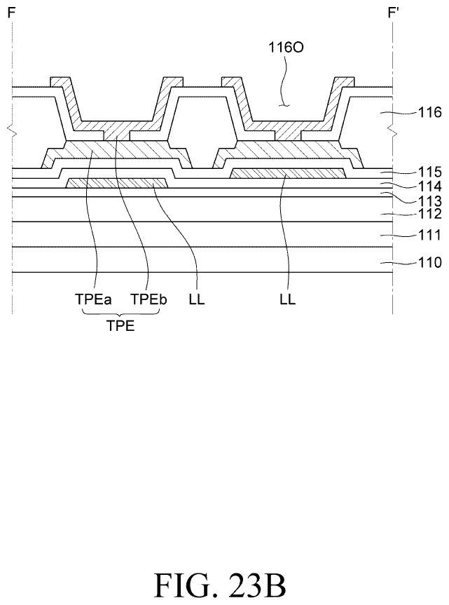

FIG. 13 is a schematic plan view of a display device according to an exemplary embodiment of the present disclosure. FIGS. 14 and 15 are enlarged plan views of an area A3 of FIG. 8. FIG. 16 is an enlarged plan view of an area A4 of FIG. 14. FIG. 17 is a cross-sectional view taken along line C-C′ of FIG. 16. FIG. 18 is an enlarged plan view of an area A5 of FIG. 16. FIG. 19 is an enlarged plan view of an area A6 of FIG. 8. FIG. 20 is a cross-sectional view taken along line D-D′ of FIG. 19. FIG. 21 is an enlarged plan view of an area A7 of FIG. 14. FIG. 22A is an enlarged plan view of an area A8 of FIG. 14. FIG. 22B is a cross-sectional view taken along line E-E′ of FIG. 22A. FIG. 23A is an enlarged plan view of an area A8 of FIG. 14. FIG. 23B is a cross-sectional view taken along line F-F′ of FIG. 23A. For convenience of explanation, in FIG. 14, among the plurality of wiring lines, the touch line TL, ground line GND, and pseudo line PS are drawn as solid lines, and the reference line RL, LOG line LOG, data line DL, and low-potential power line VSSL are drawn as dotted lines.

Referring to FIGS. 13 and 14 together, wiring lines related to the touch unit 150 are disposed in the non-display area NA. For example, the pseudo line PS, the plurality of touch lines TL, and the plurality of ground lines GND may be disposed in the non-display area NA.

Meanwhile, the display device 100 according to an exemplary embodiment of the present disclosure has a Touch On Encap (TOE) structure in which the touch unit 150 is disposed on the encapsulation layer 140, and most of the wiring lines related to the touch unit 150 may extend onto the encapsulation layer 140. Accordingly, the wiring lines related to driving the display device 100 illustrated in FIG. 4 and the wiring lines related to the touch unit 150 illustrated in FIG. 14 can be disposed on different layers, and at least some of the wiring lines may be disposed spaced apart from each other with the encapsulation layer 140 interposed therebetween.

For convenience of explanation, the wiring line related to driving the display device 100 and the wiring line related to the touch unit 150 among the wiring lines of the non-display area NA are each drawn as solid lines in FIGS. 4 and 14, but the wiring lines of the non-display area NA illustrated in FIGS. 4 and 14 are actually overlapping each other.

In addition, for convenience of explanation, each wiring line is represented as a single wiring line in FIGS. 4 and 14, but each wiring line may be composed of at least one group of wiring lines. For example, in FIG. 14, each of the touch lines TL and the pseudo lines PS is depicted as a single wiring line, but the touch lines TL and the pseudo lines PS may be composed of a group of a plurality of touch lines TL and a group of a plurality of pseudo lines PS.

Referring to FIG. 14, the plurality of first touch lines TL1 includes a portion extending in the second direction D2 from the touch pad electrode TPE of the pad portion PAD and another portion extending in the first direction D1 from the portion and disposed in a closed loop shape. For example, in the non-display area NA, the plurality of first touch lines TL1 may be formed of a vertical line portion extending from the pad portion PAD toward the encapsulation layer 140 and a horizontal line portion having a loop shape and having an empty space therein, which is disposed on the encapsulation layer 140. In addition, the plurality of first touch lines TL1 may branch from the horizontal line portions of the plurality of first touch lines TL1 in the second direction D2 and may be connected to the plurality of first touch electrodes TE1 of the display area AA.

In this case, at least one region in which the vertical line portions of the plurality of first touch lines TL1 are connected to the pad portion PAD may be disposed in the non-display area NA. For example, in FIG. 14, the vertical line portions of the plurality of first touch lines TL1 are connected to two regions of the pad portion PAD, and in FIG. 15, the vertical line portions of the plurality of first touch lines TL1 may be connected to one region of the pad portion PAD.

Additionally, the horizontal line portions of the plurality of first touch lines TL1 in the non-display area NA may form at least one loop. For example, in FIG. 14, the horizontal line portions of the plurality of first touch lines TL1 may form one loop, and in FIG. 15, the horizontal line portions of the plurality of first touch lines TL1 may form two loops.

The plurality of second touch lines TL2 include a portion extending in the second direction D2 from the touch pad electrode TPE of the pad portion PAD, and another portion extending in the first direction D1 from the portion and disposed in a bar shape. For example, in the non-display area NA, the plurality of second touch lines TL2 may be formed of a vertical line portion extending from the pad portion PAD toward the encapsulation layer 140 and a horizontal line portion disposed on the encapsulation layer 140 in a bar shape. The horizontal line portions of the plurality of second touch lines TL2 may be disposed in an empty space inside the horizontal line portions of the plurality of first touch lines TL1. That is, the horizontal line portions of the plurality of first touch lines TL1 in a loop shape may be disposed to enclose the horizontal line portions of the plurality of second touch lines TL2. Moreover, the plurality of second touch lines TL2 may be branched from the horizontal line portion of the plurality of second touch lines TL2 in the second direction D2 and connected to the plurality of second touch electrodes TE2 of the display area AA.

Meanwhile, at least a portion of the plurality of touch lines TL in the non-display area NA may be disposed outside the encapsulation layer 140. In this case, in the area where the encapsulation layer 140 is not disposed, the touch lines TL and the data lines DL are disposed relatively close together, and thus their signals may interfere with each other. Accordingly, a constant voltage line capable of shielding signals may be disposed at the intersection of the data lines DL and the touch lines TL in the area outside the encapsulation layer 140 to minimize signal interference.

For example, the low-potential power lines VSSL may be disposed between the plurality of first touch lines TL1 and the plurality of data lines DL in an area outside the encapsulation layer 140, and between the plurality of second touch lines TL2 and the plurality of data lines DL, thereby minimizing signal interference between the touch signal and the data voltage Vdata and improving touch sensing performance.

For example, the horizontal line portions of the plurality of second touch lines TL2 extending in the second direction D2 in the non-display area NA may be disposed to overlap the shorting-bar-shaped reference line RL. Accordingly, the shorting-bar-shaped reference line RL may be disposed between the plurality of data lines DL and the horizontal line portions of the plurality of second touch lines TL2, thereby functioning as a protective film that minimizes signal interference between the plurality of data lines DL and the second touch lines TL2.

Next, referring to FIG. 14, the plurality of pseudo lines PS is disposed in the non-display area NA. The plurality of pseudo lines PS may be disposed to enclose the display area AA. When the display device 100 transmits and receives a wireless signal with another device, electromagnetic interference with the touch signal may occur, and the transmission and reception performance of the wireless signal and the touch sensing performance may deteriorate. The plurality of pseudo lines PS is wiring lines for canceling the electromagnetic interference between the wireless signal and the touch signal, and the electromagnetic interference may be canceled by supplying a pseudo touch signal of an opposite phase to the touch driving signal to the plurality of pseudo lines PS.

Referring to FIG. 14, the plurality of ground lines GND is disposed between the plurality of touch lines TL and the plurality of pseudo lines PS. By discharging noise charges or the like flowing into the display panel PN to the ground voltage of the ground lines GND, the touch lines TL and pseudo lines PS may be protected, and touch sensing performance may be improved.

Some of the plurality of ground lines GND may extend along the plurality of touch lines TL and may be disposed adjacent to each of the plurality of touch lines TL. For example, some of the plurality of ground lines GND may be disposed along vertical line portions and horizontal line portions of the plurality of first touch lines TL1, and other some of the plurality of ground lines GND may be disposed along vertical line portions and horizontal line portions of the plurality of second touch lines TL2. For example, another some of the plurality of ground lines GND may be disposed between horizontal line portions of the plurality of first touch lines TL1 in a loop shape and horizontal line portions of the plurality of second touch lines TL2 and may be formed in a loop shape. For example, other some of the plurality of ground lines GND may extend along the plurality of pseudo lines PS and may be disposed adjacent to each of the plurality of pseudo lines PS.

Moreover, referring to FIGS. 13, 14, 19 and 20 together, some of the plurality of pseudo lines PS and the plurality of ground lines GND in the non-display area NA may be disposed on the encapsulation layer 140, and the remainder may be disposed in an area outside the encapsulation layer 140. For example, the plurality of pseudo lines PS may include a first pseudo line PS1, a second pseudo line PS2, a third pseudo line PS3, a fourth pseudo line PS4, and a fifth pseudo line PS5. Among the plurality of pseudo lines PS, the first pseudo line PS1 may be disposed in an area outside the encapsulation layer 140, and the second pseudo line PS2, the third pseudo line PS3, the fourth pseudo line PS4, and the fifth pseudo line PS5 may be disposed on the encapsulation layer 140.

The ground line GND may be disposed on both sides of the second pseudo line PS2, the third pseudo line PS3, the fourth pseudo line PS4, and the fifth pseudo line PS5 on the encapsulation layer 140. The ground line GND between the first pseudo line PS1 and the second pseudo line PS2 may alleviate electromagnetic interference between configurations disposed below a plurality of pseudo lines PS, for example, the gate driver GD (refer to FIG. 5A) and the plurality of pseudo lines PS. The ground line GND between the fifth pseudo line PS5 and the display area AA may function as a protective film that inhibits the configurations of the display area AA and the pseudo lines PS from being influenced by each other, thereby alleviating electromagnetic interference.

Moreover, one or more pseudo lines PS may be disposed in an area outside the encapsulation layer 140, and a ground line GND may be further disposed outside the pseudo line PS. For example, referring to FIG. 5A, one or more pseudo lines PS may be disposed in an area outside the encapsulation layer 140, and the ground line GND may be disposed in an area outside the pseudo line PS. Moreover, the ground line GND disposed at the outermost side may discharge static electricity to protect other components inside the display device 100, including the pseudo line PS.

Meanwhile, in FIG. 13, FIG. 19, and FIG. 20, it is illustrated that there are five pseudo lines PS and only the first pseudo line PS1 is disposed outside the encapsulation layer 140. However, the disposition and number of the pseudo lines PS may be changed in consideration of the size of the non-display area NA, the formation area of the encapsulation layer 140, or the like, and the embodiments of the present disclosure are not limited thereto.

Next, referring to FIG. 16, in the upper region of the non-display area NA, the widths of the plurality of first touch lines TL1 may be narrowed at points where the plurality of first touch lines TL1 and the plurality of second touch lines TL2 intersect. The width of a portion of the plurality of first touch lines TL1 that intersects the plurality of second touch lines TL2 may be narrower than the width of another portion that does not intersect the plurality of second touch lines TL2. By configuring the widths of the plurality of first touch lines TL1 to be narrow at points where the plurality of first touch lines TL1 and the plurality of second touch lines TL2 intersect, interference between the plurality of first touch lines TL1 and the plurality of second touch lines TL2 can be minimized.

Referring to FIGS. 16 and 17 together, the first touch line TL1, the second touch line TL2, and the ground line GND may be formed as a double wiring line structure. For example, each of the first touch line TL1, the second touch line TL2, and the ground line GND may be formed as a bilayer structure of the bridge metal BM on the touch buffer layer 151 and the sensor metal SM on the touch insulation layer 152. In addition, the bridge metal BM and the sensor metal SM of each of the first touch line TL1, the second touch line TL2, and the ground line GND may be connected to each other through the contact hole of the touch insulation layer 152.

In this case, at the intersection of the first touch line TL1 and the second touch line TL2, the first touch line TL1 and the second touch line TL2 may use different metals. For example, at the intersection of the first touch line TL1 and the second touch line TL2, the first touch line TL1 may be composed only of a bridge metal BM on the touch insulation layer 152, and the second touch line TL2 may be composed only of a sensor metal SM between the touch buffer layer 151 and the touch insulation layer 152.

Meanwhile, the cathode 123 may be electrically connected to the low-potential power line VSSL using an anode pattern 121a in the non-display area NA. For example, the anode pattern 121a of the same material as the anode 121 may be connected to the low-potential power line VSSL in the non-display area NA. In addition, an opening in which the anode pattern 121a is exposed may be formed in the bank 117, and the cathode 123 may be extended from the display area AA to the opening. Therefore, the cathode 123, the anode pattern 121a, and the low-potential power line VSSL may be electrically connected to each other.

In addition, in the non-display area NA, the multiplexer circuit MUX, the light inspection transistor AP, the electrostatic discharge protection circuit ESD, and the like are disposed below the touch unit 150. Moreover, the shorting-bar-shaped reference line RL, the high-potential power line VDDL, and the low-potential power line VSSL, or the like described in FIG. 4 may also be disposed.

Next, referring to FIG. 18, in the area below the non-display area NA, the width of the plurality of second touch lines TL2 may be varied at a point where the plurality of first touch lines TL1 and the plurality of second touch lines TL2 intersect, thereby compensating for the capacitance variation of each of the plurality of touch lines TL.

For example, each of the plurality of touch lines TL may have a different length depending on the shape of the display device 100, the position of the touch electrode TE, or the like. For example, when the display device 100 has a non-rectangular shape, the lengths of the plurality of touch lines TL may vary by region. When the lengths of the plurality of touch lines TL are different, the capacitance variation may occur depending on the difference in the overlapping size between the plurality of touch lines TL. For example, when the lengths of the plurality of second touch lines TL2 are different, the overlapping size between each of the plurality of second touch lines TL2 and the first touch line TL1 is different, and the capacitance value between each of the plurality of second touch lines TL2 and the first touch line TL1 may also vary. Accordingly, by varying the width of the second touch line TL2, the overlapping size between the first touch line TL1 and the second touch line TL2 and the capacitance value resulting therefrom may be controlled.

For example, when the second touch line TL2 on the left among the three second touch lines TL2 has a relatively short length, the width of the second touch line TL2 may be widened in three areas among the intersection areas of the second touch line TL2 on the left and the plurality of first touch lines TL1. Therefore, it is possible to increase the overlapping size of the first touch line TL1 and the second touch line TL2 and increase the capacitance. For example, when the second touch line TL2 on the right among the three second touch lines TL2 has a relatively long length, the width of the second touch line TL2 may be widened in only one area among the intersection areas of the second touch line TL2 and the plurality of first touch lines TL1. Therefore, by varying the width of the second touch line TL2 at the intersection points of the first touch lines TL1 and the second touch lines TL2, the capacitance variation of each of the plurality of touch lines TL can be reduced.

Meanwhile, referring to FIG. 21 and FIG. 5A together, the area where the LOG line LOG is disposed is the area where the gate driver GD is disposed, and the scan signal driver SCAN Driver or the light emission signal driver EM Driver that constitutes the gate driver GD may be disposed together. For example, in the non-display area NA, the light emission signal driver EM Driver and the scan signal driver SCAN Driver may be disposed, and the LOG line LOG, for example, an emission clock signal line EM CLK, may be disposed between the light emission signal driver EM Driver and the scan signal driver SCAN Driver.

In this case, the plurality of pseudo lines PS may be disposed in the non-display area NA and may overlap the gate driver GD (refer to FIG. 5A), and accordingly, electromagnetic interference or the like may occur between the plurality of pseudo lines PS and the gate driver GD. Accordingly, the width of the ground line GND disposed adjacent to the plurality of pseudo lines PS and overlapping the gate driver GD may be formed wider. For example, the ground line GND may be disposed to cover all of the scan signal driver SCAN Driver and the light emission signal driver EM Driver of the gate driver GD and the LOG line LOG. For example, the width of the ground line GND overlapping the gate driver GD may be wider than the width of the gate driver GD. For example, the width of the ground line GND overlapping the gate driver GD is greater than the sum of the width of the scan signal driver SCAN Driver and the width of the light emission signal driver EM Driver. The ground line GND may function as a protective film that shields the signal of the gate driver GD from affecting the plurality of pseudo lines PS. Therefore, by forming the ground line GND overlapping the gate driver GD with a wide width, which is disposed on one side of the plurality of pseudo lines PS, the electromagnetic interference between the gate driver GD and the pseudo lines PS can be minimized.

Next, referring to FIGS. 22A and 23B, the pad portion PAD may further include a plurality of touch pad electrodes TPE to which wiring lines related to driving the display panel PN are connected, in addition to a plurality of pad electrodes PE to which wiring lines related to the touch unit 150 are connected. The plurality of touch pad electrodes TPE may be formed in various structures.

For example, referring to FIGS. 22A and 22B, the touch pad electrode TPE is disposed on the pad portion PAD. The flexible film COF may be bonded on the touch pad electrode TPE to connect the touch driver TD and the touch unit 150. The touch pad electrode TPE includes a first pad conductive layer TPEa and a second pad conductive layer TPEb on the first pad conductive layer TPEa.

The first pad conductive layer TPEa is disposed between the second interlayer insulating layer 115 and the planarization layer 116, and the planarization layer 116 includes an opening 116O through which the first pad conductive layer TPEa is exposed. The opening 116O of the planarization layer 116 may have a smaller size than the first pad conductive layer TPEa.

The second pad conductive layer TPEb is disposed on the planarization layer 116. The second pad conductive layer TPEb may be in contact with the first pad conductive layer TPEa at the opening 116O of the planarization layer 116. The second pad conductive layer TPEb may be formed using the same material and the same process as the conductive layer of the touch electrode TE. The second pad conductive layer TPEb may have a smaller size than the opening 116O of the planarization layer 116.

Referring to FIGS. 23A and 23B, the touch pad electrode TPE includes the first pad conductive layer TPEa and the second pad conductive layer TPEb on the first pad conductive layer TPEa.

The first pad conductive layer TPEa is disposed between the second interlayer insulating layer 115 and the planarization layer 116, and the planarization layer 116 includes the opening 116O through which the first pad conductive layer TPEa is exposed. The opening 116O of the planarization layer 116 may have a smaller size than the first pad conductive layer TPEa.

At least one of the insulating layers of the touch unit 150 is disposed on the planarization layer 116, and the second pad conductive layer TPEb is disposed on the insulating layer of the touch unit 150. For example, the touch buffer layer 151 may be disposed between the planarization layer 116 and the second pad conductive layer TPEb. The touch buffer layer 151 may overlap the opening 116O of the planarization layer 116 and have an opening that is smaller in size than the opening 116O of the planarization layer 116. The second pad conductive layer TPEb may be in contact with the first pad conductive layer TPEa through the opening of the touch buffer layer 151 and the opening 116O of the planarization layer 116.

However, the touch insulation layer 152 may be additionally disposed in addition to the touch buffer layer 151 between the planarization layer 116 and the second pad conductive layer TPEb, or the touch insulation layer 152 may be disposed instead of the touch buffer layer 151, but the present disclosure is not limited thereto.

In this case, the plurality of link lines LL may be disposed under the plurality of touch pad electrodes TPE. The plurality of link lines LL may be composed of various layers of conductive layers. For example, referring to FIG. 22B, the plurality of link lines LL may be disposed between the gate insulating layer 113 and the first interlayer insulating layer 114, and may be connected to another touch pad electrode TPE or another pad electrode PE. For another example, referring to FIG. 23B, some of the plurality of link lines LL may be disposed between the gate insulating layer 113 and the first interlayer insulating layer 114, and other some of the plurality of link lines LL may be disposed between the first interlayer insulating layer 114 and the second interlayer insulating layer 115.

Accordingly, in the display device 100 according to an exemplary embodiment of the present disclosure, the touch unit 150 is disposed on the encapsulation layer 140, and various configurations may be disposed to improve the performance of the touch unit 150. For example, the shifting area in which the plurality of first touch lines TL1 are shifted and extended between the plurality of first touch electrodes TE1 may be formed. Therefore, the gap between the contact hole through which the first touch lines TL1 and the first touch electrodes TE1 are connected and the second touch electrodes TE2 may be formed to be constant, and the parasitic capacitance between the first touch lines TL1 and the second touch electrodes TE2 may be configured to be uniform. For example, the delay of the touch signal may be minimized by applying a dual feeding structure that connects one or more touch lines TL to the line of one touch electrode TE or a multi-feeding structure that connects the touch line TL to each of the touch electrodes TE.

For another example, the plurality of pseudo lines PS to which signals having opposite phases to those of touch lines TL are applied may be disposed in the non-display area NA to suppress electromagnetic interference that occurs when transmitting and receiving wireless signals. For example, the ground line GND may be disposed around the plurality of pseudo lines PS to minimize interference between signals of the plurality of pseudo lines PS and the gate driver GD, and to protect other components of the display device 100 including the plurality of pseudo lines PS from static electricity. For example, in the non-display area NA, various lines for driving the display panel PN and various wiring lines for driving the touch unit 150 may overlap each other. Accordingly, the data lines DL and touch lines TL may overlap each other, and the low-potential power line VSSL or the reference line RL, which functions as a shielding film, may be disposed between the touch lines TL and the data lines DL to inhibit their signals from interfering with each other.

Therefore, in the display device 100 according to an exemplary embodiment of the present disclosure, by applying the above configuration, the capacitance variation of the touch electrode TE and the touch line TL, signal interference or electromagnetic interference between the touch unit 150 and other configurations can be reduced, thereby improving the touch sensing performance of the touch unit 150.

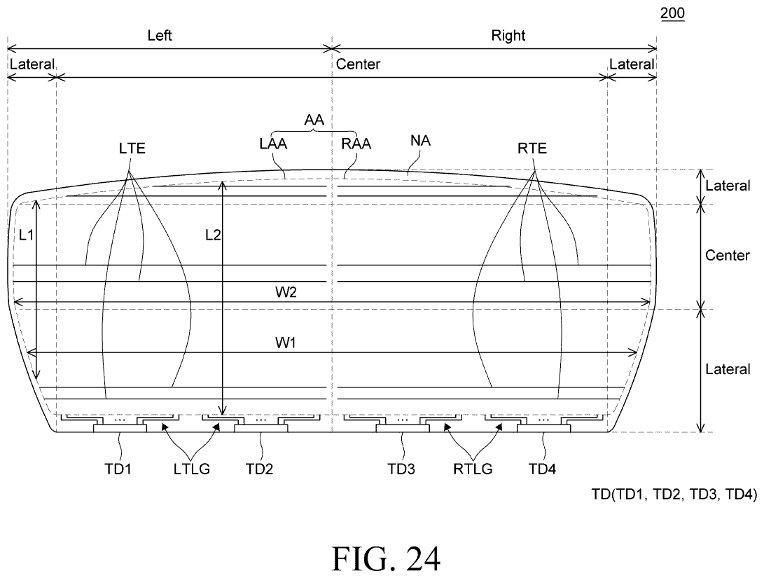

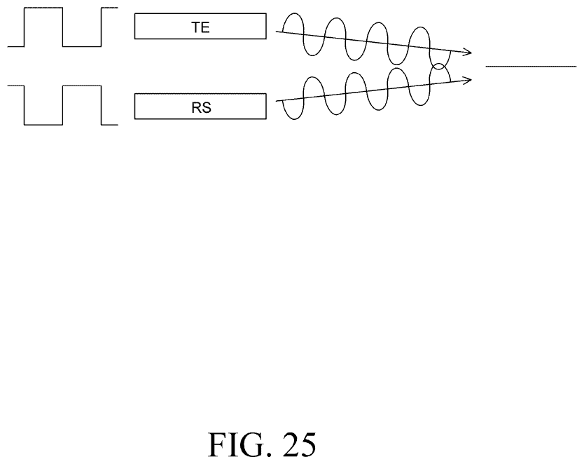

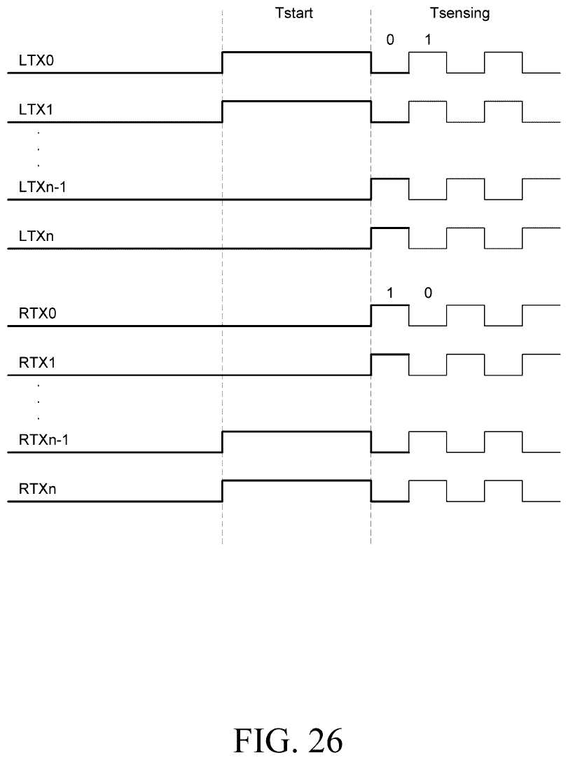

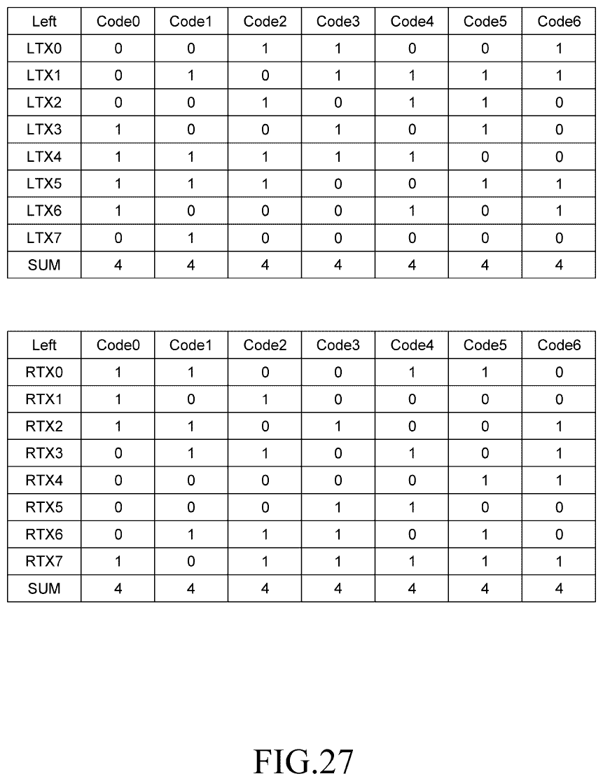

FIG. 24 is a schematic plan view of a display device according to another exemplary embodiment of the present disclosure. FIG. 25 is a diagram illustrating a configuration of a touch unit of a display device according to another exemplary embodiment of the present disclosure. FIG. 26 is a view for explaining driving of a touch unit of a display device according to another exemplary embodiment of the present disclosure. FIG. 27 is a view for explaining driving of a touch unit of a display device according to another exemplary embodiment of the present disclosure. A display device 200 of FIGS. 24 to 27 is substantially identical in configuration to the display device 100 of FIGS. 1 to 23B, except for a shape of the display device 200 and a touch unit 150. Therefore, repeated descriptions of the identical components will be omitted. In FIG. 24, for the convenience of description, only some configurations are illustrated.

Referring to FIG. 24, when the display device 200 is formed in a heterogeneous shape, a central portion (Center) is formed larger than an outer portion (Lateral). In other words, based on a first direction, a width W1 of the outer portion (Lateral) of the display area AA, which is located above and below the central portion (Center) of the display area AA, may be shorter than a width W2 of the central portion (Center). In addition, based on a second direction intersecting the first direction, a length L1 of the outer portion (Lateral) of the display area AA, which is located on the left and right sides of the central portion (Center) of the display area AA, may be shorter than a length L2 of the central portion (Center).

Accordingly, the plurality of touch electrodes LTE and RTE formed on the display area AA may have different lengths depending on positions. That is, the lengths of the touch electrodes LTE and RTE disposed in the outer portion of the display area AA may be shorter than the lengths of the touch electrodes LTE and RTE disposed in the central portion of the display area AA.

Noise such as electromagnetic interference may be different for each touch electrode LTE or RTE due to the lengths of different touch electrodes LTE and RTE. That is, the electromagnetic interference generated in the touch electrodes LTE and RTE disposed in the central portion of the display area AA may be greater than the electromagnetic interference of the touch electrodes LTE and RTE disposed in the outer portion of the display area AA.

In order to reduce such electromagnetic interference, the plurality of pseudo lines PS may be disposed to surround the display area AA. As shown in FIG. 25, the plurality of pseudo lines PS may be applied with a touch driving signal supplied to the plurality of touch electrodes LTE and RTE and a pseudo touch signal having an inverse phase. That is, since the electromagnetic interference generated from the plurality of touch electrodes LTE and RTE and the electromagnetic interference generated from the plurality of pseudo lines PS are reversed by being in phase with each other, noise may be minimized.

Referring back to FIG. 24, the display area AA may be divided into a left display area LAA and a right display area RAA. A first touch line group LTLG may be connected to the left display area LAA to supply a first touch driving signal LTXn, and a second touch line group RTLG may be connected to the right display area RAA to supply a second touch driving signal RTXn.

The left display area LAA and the right display area RAA are formed to be spaced apart from each other, and a first touch line group LTLG and a second touch line group RTLG may be disposed between the left and right display area LAA and RAA and the touch driver TD. In addition, the first touch line group LTLG may be disposed on both sides of the left display area LAA and supply the same first touch driving signal LTXn on both sides. The second touch line group RTLG may be disposed on both sides of the right display area RAA and may supply the same second touch driving signal RTXn on both sides. That is, the first touch driving signal LTXn and the second touch driving signal RTXn may be supplied in a dual feeding structure. The touch driver TD may supply a first touch driving signal LTXn and a second touch driving signal RTXn to the first touch line group LTLG and the second touch line group RTLG through a flexible film connected to the touch pad electrode TPE. For example, the touch driver TD may include a first touch driver TD1 and a second touch driver TD2 which supply signals to the first touch line group LTLG of the left display area LAA, and a third touch driver TD3 and a fourth touch driver TD4 which supply signals to the second touch line group RTLG of the right display area RAA.

Referring to FIGS. 26 and 27, the touch driver TD may drive a first touch driving signal LTXn and a second touch driving signal RTXn in a code division multiplexing (CDM) manner during a touch sensing period Tsensing.

In other words, according to the code division multiplexing method, a code expressed in binary number may be allocated for each of a plurality of touch lines. The sum of each code applied to the plurality of touch lines may be half the number of applied codes.

For example, when 8 codes are applied, a total of 7 codes excluding the start signal may be supplied to the 8 touch lines. In this case, since the code is represented by a binary number, the sum of the codes applied to the eight touch lines for each code may be “4,” and the sum may be “28.”

However, the number of applied codes is not limited thereto, and may be selected as 12 codes or 16 codes depending on the design.

In this way, when driven in the code division multiplexing manner, the first touch driving signal LTXn and the second touch driving signal RTXn are applied to the left display area LAA and the right display area RAA, respectively, and the first touch driving signal LTXn and the second touch driving signal RTXn may be concurrently applied. In addition, the first touch driving signal LTXn and the second touch driving signal RTXn are supplied in reverse phase with each other, and the sum of codes may be offset values in the first touch driving signal LTXn and the second touch driving signal RTXn driven in a code division multiplexing manner. That is, it may be “0”.

The touch driver TD may supply first and second touch driving signals LTXn and RTXn of analog voltage levels to the plurality of touch electrodes LTE and RTE through the first touch line group LTLG and the second touch line group RTLG in accordance with a code set according to a code division multiplexing method.

In other words, the first touch driving signal LTXn supplied to the first touch line group LTLG is supplied at a high voltage level or a low voltage level for each touch line. In this case, the first touch driving signal LTXn is supplied with the same number of times of high voltage level and low voltage level to cancel electromagnetic interference.

In addition, the second touch driving signal RTXn supplied to the second touch line group RTLG may be supplied at a low voltage level or a high voltage level for each touch line in response to the first touch driving signal LTXn supplied to the first touch line group LTLG. In this case, the second touch driving signal RTXn may be supplied with the low voltage level and the high voltage level the same number of times, such that electromagnetic interference may be canceled out.

In addition, for each touch line, the first touch driving signal LTXn and the second touch driving signal RTXn corresponding thereto are in reverse phase, and accordingly, electromagnetic interference may be canceled for each touch line.

Before the touch sensing period Tsensing, the touch start period Tstart may operate. The touch start period Tstart may be a signal period notifying the start of the touch sensing period Tsensing.

In the touch start period Tstart, like the touch sensing period Tsensing, at least some of the first touch driving signals LTXn or the second touch driving signal RTXn may be supplied at a high voltage level, and the remaining first touch driving signals LTXn or the second touch driving signal RTXn may be supplied at a low voltage level. In addition, when the first touch driving signal LTXn is supplied at a high voltage level, the second touch driving signal RTXn corresponding thereto may be supplied at a low voltage level.

For example, in the case where the first touch driving signal LTXn applied to the n-th touch line of the first touch line group LTLG during the touch start period Tstart is a high voltage level, the first touch driving signal LTXn of the n-th touch line in the touch sensing period TXn may start at a low voltage level and repeat the swing at a high voltage level. Further, the n-th touch line of the second touch line group RTLG corresponding thereto is a low voltage level during the touch start period Tstart, and starts at a high voltage level during the touch sensing period Tsensing to repeat the swing to a low voltage level.

In this way, when the first touch driving signal LTXn and the second touch driving signal RTXn are driven in reverse phase with each other, noise such as electromagnetic interference may be minimized. When configured together with the pseudo line PS, a higher noise removal effect may be obtained.

In addition, even if a separate pseudo line PS is not configured, electromagnetic interference may be sufficiently cancelled, thereby reducing noise components. In this case, since the area for disposing the pseudo line PS may be deleted, the bezel portion may be further reduced, and the aesthetics of the display device 200 may be maximized.

The exemplary embodiments of the present disclosure can also be described as follows:
According to an aspect of the present disclosure, there is provided display device. The display device includes a substrate including a display area in which a plurality of sub-pixels is disposed and a non-display area surrounding the display area. The display device further includes an encapsulation layer disposed on the substrate. The display device further includes a touch unit disposed on the encapsulation layer. The touch unit includes: a plurality of touch electrodes disposed in the display area and configured by a touch metal; and a first touch line group and a second touch line group disposed in the non-display area and respectively connected to the plurality of touch electrodes. A first touch driving signal applied to the first touch line group is in reverse phase with a second touch driving signal applied to the second touch line group.

Lengths of the plurality of touch electrodes may be different from each other.

An outer touch electrode among the plurality of touch electrodes disposed at an upper portion or a lower portion of the display area may have a shorter length than a central touch electrode among the plurality of touch electrodes disposed at a central portion of the display area.

The amount of electromagnetic interference (e.g., electromagnetic interference level) of the outer touch electrode is different from the amount of electromagnetic interference of the central touch electrode.

The amount of electromagnetic interference of the outer touch electrode may be greater than the amount of electromagnetic interference of the central touch electrode.

At least some of the first touch driving signals may be supplied at a high voltage level during a touch start period that is driven before a touch sensing period, and the touch sensing period is a period in which the first touch driving signals and the second touch driving signals are supplied.

While at least some of the first touch driving signals may be supplied at the high voltage level during the touch start period, corresponding second touch driving signals may be supplied at a low voltage level.

While at least some of the first touch driving signals may be supplied at the high voltage level during the touch start period, remaining first touch driving signals may be supplied at a low voltage level.

The display area may include a left display area and a right display area, the first touch line group may supply the first touch driving signal to the left display area, and the second touch line group may supply the second touch driving signal to the right display area.

The display area may be divided into the left display area and the right display area, and the left display area and the right display area may be spaced apart from each other.

The display device may further comprise a touch driver configured to supply signals to each of the first touch line group and the second touch line group. The first touch line group and the second touch line group may be disposed between the left and right display area and the touch driver.

The first touch line group and the second touch line group may be respectively connected to the left display area and the right display area in a dual feeding structure.

The first touch driving signal and the second touch driving signal may be concurrently applied.

The first touch driving signal and the second touch driving signal may be supplied in a code division multiplexing manner.

The first touch driving signal and the second touch driving signal corresponding to the first touch driving signal may cancel electromagnetic interference with each other.

A length of a central portion of the display area may be different from a length of an outer portion of the display area.

A width of a central portion of the display area may be different from a width of an outer portion of the display area.

The first touch driving signal and the second touch driving signal may be supplied through a flexible film connected to a touch pad electrode.

The flexible film may connect a touch driver and the touch unit.

The touch pad electrode may include a first pad conductive layer and a second pad conductive layer on the first pad conductive layer.

Although the exemplary embodiments of the present disclosure have been described in detail with reference to the accompanying drawings, the present disclosure is not limited thereto and may be embodied in various forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described embodiments are illustrative in all aspects and do not limit the present disclosure. All the technical concepts in the equivalent scope of the present disclosure should be construed as falling within the scope of the present disclosure.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device comprising:
a substrate including a display area in which a plurality of sub-pixels is disposed and a non-display area adjacent to the display area;
an encapsulation layer disposed on the substrate; and
a touch unit disposed on the encapsulation layer,
wherein the touch unit includes:
a plurality of touch electrodes disposed in the display area and formed of a touch metal; and
a first touch line group and a second touch line group disposed in the non-display area and respectively connected to the plurality of touch electrodes, and
wherein a first touch driving signal applied to the first touch line group is in a reverse phase relationship with a second touch driving signal applied to the second touch line group.

2. The display device according to claim 1, wherein lengths of the plurality of touch electrodes are different from each other.

3. The display device according to claim 2, wherein an outer touch electrode among the plurality of touch electrodes disposed at an upper portion or a lower portion of the display area has a shorter length than a central touch electrode among the plurality of touch electrodes disposed at a central portion of the display area.

4. The display device according to claim 3, wherein an electromagnetic interference level of the outer touch electrode is different from that of the central touch electrode.

5. The display device according to claim 4, wherein the electromagnetic interference level of the outer touch electrode is greater than that of the central touch electrode.

6. The display device according to claim 1, wherein at least some of the first touch driving signals are supplied at a high voltage level during a touch start period that occurs before a touch sensing period, the touch sensing period being a period in which the first touch driving signals and the second touch driving signals are supplied.

7. The display device according to claim 6, wherein while the at least some of the first touch driving signals are supplied at the high voltage level during the touch start period, corresponding second touch driving signals are supplied at a low voltage level.

8. The display device according to claim 6, wherein while the at least some of the first touch driving signals are supplied at the high voltage level during the touch start period, other first touch driving signals are supplied at a low voltage level.

9. The display device according to claim 1, wherein the display area includes a left display area and a right display area, the first touch line group supplies the first touch driving signal to the left display area, and the second touch line group supplies the second touch driving signal to the right display area.

10. The display device according to claim 9, wherein the display area is divided into the left display area and the right display area, and the left display area and the right display area are spaced apart from each other.

11. The display device according to claim 10, further comprising:
a touch driver configured to supply signals to each of the first touch line group and the second touch line group,
wherein the first touch line group and the second touch line group are disposed between the left and right display areas and the touch driver.

12. The display device of claim 11, wherein the first touch line group and the second touch line group are respectively connected to the left display area and the right display area in a dual feeding structure.

13. The display device according to claim 1, wherein the first touch driving signal and the second touch driving signal are concurrently applied.

14. The display device according to claim 13, wherein the first touch driving signal and the second touch driving signal are supplied in a code division multiplexing manner.

15. The display device according to claim 13, wherein the first touch driving signal and the corresponding second touch driving signal cancel electromagnetic interference with each other.

16. The display device according to claim 1, wherein a length of a central portion of the display area is different from a length of an outer portion of the display area.

17. The display device according to claim 1, wherein a width of a central portion of the display area is different from a width of an outer portion of the display area.

18. The display device according to claim 1, wherein the first touch driving signal and the second touch driving signal are supplied through a flexible film connected to a touch pad electrode.

19. The display device according to claim 18, wherein the flexible film connects a touch driver and the touch unit.

20. The display device according to claim 18, wherein the touch pad electrode includes a first pad conductive layer and a second pad conductive layer on the first pad conductive layer.
